(19) United States
(12) Patent Application Publication
(10) Pub. No.: US 2026/0057134 A1
(43) Pub. Date: Feb. 26, 2026

(54) TECHNIQUES FOR DESIGNING A HEATING, VENTILATION, AND AIR CONDITIONING SYSTEM

(71) Applicant: Conduit Tech, Inc., Somerville, MA (US)

(72) Inventors: Shelby Ann Breger, Somerville, MA (US); Marisa Kamakshi Puli, Reddy, MA (US); Gavin Hackeling, Phiadelphia, PA (US)

(73) Assignee: Conduit Tech, Inc., Somerville, MA (US)

(21) Appl. No.: 19/124,570

(22) PCT Filed: Nov. 13, 2023
(86) PCT No.: PCT/US2023/079505

§ 371 Date: Apr. 25, 2025

Related U.S. Application Data
(60) Provisional application No. 63/425,281, filed on Nov. 14, 2022.

(51) Int. Cl. G06F 30/18

(52) U.S. Cl. CPC G06F 30/18

(57) ABSTRACT

Described herein are techniques for determining an HVAC system design for a space. The techniques makes the process of designing an HVAC system (e.g., for a contractor or engineer) more efficient by allowing a user to determine an HVAC system design for the space using a single device (e.g., a smartphone or table). The device obtains information about the space (e.g., boundary dimensions) and performs an HVAC analysis to determine HVAC system properties suitable for the space. The device determines an HVAC system design proposal for the space based on the determined HVAC system properties, and presents the design proposal to the user (e.g., in a GUI).

### RELATED APPLICATIONS

This application claims benefit under 35 U.S.C. § 119(e) of U.S. Provisional Application No. 63/425,281 titled “TECHNIQUES FOR DESIGNING A HEATING, VENTILATION, AND AIR CONDITIONING SYSTEM” filed on Nov. 14, 2022, which is incorporated by reference herein in its entirety.

### FIELD

Described herein is a system for determining a heating, ventilation, and air conditioning (HVAC) system design for a building.

### BACKGROUND

An HVAC system for a building (e.g., a home, office, etc.) is typically designed to suit the needs of the building. The HVAC system design may be determined based on a level of comfort desired in the building, energy expenditure, intended use of the building, and/or other considerations. A process of designing an HVAC system may involve performing various calculations for determining different aspects of the design. As part of designing an HVAC system, HVAC calculations may be performed to determine an equipment size for the HVAC system, suitable equipment types for the HVAC system, duct design (e.g., type of duct, number of registers, size of duct) for the building, and/or other building structure upgrades such as insulation and sealing.

### SUMMARY

Described herein are techniques for determining an HVAC system design for a space. The techniques make the process of designing an HVAC system (e.g., for a contractor, salesperson, engineer, or other user) more efficient by allowing a user to determine an HVAC system design for the space using a single device (e.g., a smartphone or tablet). The device obtains information about the space (e.g., boundary dimensions) and performs an HVAC analysis to determine HVAC system properties suitable for the space. The device determines an HVAC system design proposal for the space based on the determined HVAC system properties and presents the design proposal to the user (e.g., in a GUI).

Some embodiments provide a system for determining a heating, ventilation, and air conditioning (HVAC) system design for a space in a building. The system comprises: at least one imaging sensor; at least one processor; and a non-transitory computer-readable storage medium storing instructions that, when executed by the at least one processor, cause the at least one processor to: obtain, using the at least one imaging sensor, spatial measurement data for the space; determine, using the spatial measurement data, information about boundaries of the space; perform an HVAC analysis using the information about the boundaries of the space to determine HVAC system properties suitable for the space; and determine, using the HVAC system properties suitable for the space, an HVAC system design proposal for the space.

In some embodiments, the information about the boundaries of the space includes: an indication of one or more windows in the space; an indication of one or more walls in the space; dimensions of the one or more windows in the space; dimensions of the one or more walls in the space; a surface area of the one or more windows in the space; and/or a surface area of the one or more walls in the space.

In some embodiments, performing the HVAC analysis comprises: transmitting, to at least one computer separate from the system, the information about the boundaries of the space; and receiving, from the at least one computer, data indicating the HVAC system properties suitable for the space.

In some embodiments, obtaining the results of the HVAC analysis comprises: performing, by the at least one processor, one or more HVAC system design processes using the information about the boundaries of the space to determine the HVAC system properties suitable for the space.

In some embodiments, the HVAC system properties determined from performing the HVAC analysis comprise an HVAC equipment size, an equipment type, and/or a duct system.

In some embodiments, determining, using the spatial measurement data, the information about the boundaries of the space comprises: identifying one or more structures in the space, wherein the one or more structures include one or more walls, windows, and/or doors; and determining dimensions of the one or more structures. In some embodiments, the instructions further cause the at least one processor to: determine, for each of the one or more structures, values of one or more attributes of the structure. In some embodiments, determining, for each of the one or more structures, the values of the one or more attributes of the structure comprises: loading a template indicating attribute values for one or more structure categories; identifying attribute values specified by the template for a category of the structure, the attribute values comprising values for the one or more attributes of the structure; and setting the values of the one or more attributes of the values for the one or more attributes specified by the template.

In some embodiments, the instructions further cause the at least one processor to: obtain information indicating building material of the building; and perform the HVAC analysis using the information indicating the building material of the building.

In some embodiments, the instructions further cause the at least one processor to: obtain information indicating a geographic location of the building; and perform the HVAC analysis using the geographic location of the building.

In some embodiments, the at least one imaging sensor comprises a light detection and ranging (LiDAR) sensor and obtaining, using the at least one imaging sensor, spatial measurement data for the space comprises: using the LiDAR sensor to identify boundaries in the space.

In some embodiments, determining, using the spatial measurement data, the information about the boundaries of the space comprises: generating a three-dimensional (3D) floorplan of the space; and determining the information about the boundaries of the space using the 3D floor plan of the space. In some embodiments, the instructions further cause the at last one processor to: receive, through a graphical user interface (GUI), user input indicating an adjustment to the 3D floorplan of the space; and update the 3D floorplan of the space in response to the user input.

In some embodiments, the HVAC system design proposal includes equipment and/or installation material and the instructions further cause the at least one processor to: access, from a database separate from the system, pricing information for the equipment and/or the installation material.

In some embodiments, the instructions further cause the at least one processor to: obtain an image of the space; and generate a GUI indicating the boundary dimensions of the space in the image. In some embodiments, the instructions further cause the at least one processor to: receive, through the GUI, user input indicating a modification to at least one of the boundary dimensions; and update, using the user input, the at least one boundary dimension.

In some embodiments, the HVAC system design proposal comprises a plurality of HVAC system designs and the instructions further cause the at least one processor to: generate a GUI presenting the plurality of HVAC system design proposals to a user; and receiving, through the GUI, user input indicating a selected HVAC system design of the plurality of HVAC system designs. In some embodiments, the instructions further cause the at least one processor to generate installation instructions and an equipment list organized by room for the selected HVAC system design.

Some embodiments provide a method of determining an HVAC system design for a space in a building. The method comprises obtaining, using at least one imaging sensor, spatial measurement data for the space; determining, with at least one processor using the spatial measurement data, information about boundaries in the space; performing, with the at least one processor using the boundary dimensions of the space, an HVAC analysis using the information about the boundaries of the space to determine HVAC system properties suitable for the space; and determining, with the at least one processor using the HVAC system properties suitable for the space, an HVAC system design proposal for the space.

Some embodiments provide a non-transitory computer-readable storage medium storing instructions that, when executed by at least one processor, cause the at least one processor to perform a method of determining an HVAC system design for space in a building, the method comprising: obtaining, using at least one imaging sensor, spatial measurement data for the space; determining, using the spatial measurement data, information about boundaries in the space; performing, using the boundary dimensions of the space, an HVAC analysis using the information about the boundaries of the space to determine HVAC system properties suitable for the space; and determining, using the HVAC system properties suitable for the space, an HVAC system design proposal for the space. The foregoing summary is non-limiting.

### DESCRIPTION OF DRAWINGS

Various aspects and embodiments will be described with reference to the following figures. It should be appreciated that the figures are not necessarily drawn to scale. Items appearing in multiple figures are indicated by the same or a similar reference number in all the figures in which they appear.

FIG. 1A is an example environment in which some embodiments of the technology described herein may be implemented.

FIG. 1B is an example interaction among the entities of FIG. 1A to determine an HVAC system design proposal, according to some embodiments of the technology described herein.

FIG. 1C is an example presentation of an HVAC system design proposal on a device FIG. 1A, according to some embodiments of the technology described herein.

FIG. 1D is an example presentation of an interface that allows editing attributes of structures in a 3D floorplan of a space, according to some embodiments of the technology described herein.

FIG. 2A is an example process of determining an HVAC system design proposal, according to some embodiments of the technology described herein.

FIG. 2B is an example process of using a template in determining an HVAC system design proposal, according to some embodiments of the technology described herein.

FIG. 3A is an example process of obtaining information about one or more spaces using one or more imaging sensors, according to some embodiments of the technology described herein.

FIG. 3B is an example process of transmitting boundary information from a device to another system, according to some embodiments of the technology described herein.

FIGS. 4A-4B illustrate an example sequence of steps of determining an HVAC system design, according to some embodiments of the technology described herein.

FIG. 5 is an example graphical user interface (GUI) through which a system may receive user input indicating comfort considerations for an HVAC system design, according to some embodiments of the technology described herein.

FIG. 6 is an example GUI through which a system may receive user input indicating information about one or more spaces, according to some embodiments of the technology described herein.

FIGS. 7A-7C illustrate an example GUI through which a system may receive an image of a space, according to some embodiments of the technology described herein.

FIGS. 8A-8E illustrate the use of imaging sensor(s) of a device to generate a three-dimensional (3D) floorplan of a floor in a building, according to some embodiments of the technology described herein.

FIG. 9A is an example 3D floorplan, according to some embodiments of the technology described herein.

FIG. 9B illustrates association of a user provided note with a portion of the 3D floorplan of FIG. 9A, according to some embodiments of the technology described herein.

FIG. 10 is an example GUI displaying results of an HVAC analysis, according to some embodiments of the technology described herein.

FIG. 11 is an example GUI displaying results of an HVAC analysis, according to some embodiments of the technology described herein.

FIG. 12 is an example GUI through which a system may receive user input indicating features for an HVAC system design, according to some embodiments of the technology described herein.

FIG. 13 is an example GUI displaying an HVAC system design proposal, according to some embodiments of the technology described herein.

FIG. 14 is an example GUI displaying an HVAC system design proposal comprising of multiple HVAC system designs that a user may select from, according to some embodiments of the technology described herein.

FIG. 15 is an example GUI through which a system may allow a user to add features to improve energy efficiency, according to some embodiments of the technology described herein.

FIGS. 16A-16B illustrate example GUIs for identifying incentives for an HVAC system design, according to some embodiments of the technology described herein.

FIG. 17 is an example GUI showing a list of templates that can be accessed for determining an HVAC system design proposal, according to some embodiments of the technology described herein.

FIG. 18 is an example GUI for adjusting a 3D model (e.g., a 3D floorplan) obtained from scanning a space, according to some embodiments of the technology described herein.

FIG. 19 is an example GUI for editing attributes of a structure in a space, according to some embodiments of the technology described herein.

FIG. 20 is an example computer system which may be used to implement some embodiments of the technology described herein.

### DETAILED DESCRIPTION

Described herein are systems and techniques of automatically determining an HVAC system design for a space in a building. The building may be a residential building (e.g., a home, apartment building, townhouse, or other residential building), a commercial building (e.g., a retail space, an office, or other residential building), or other type of building. The space may be the entire building, a floor of the building, a room of the building, or other portion of the building.

For an HVAC system of a building to work properly, the HVAC system needs to be designed based on various aspects of the building including characteristics of the building (e.g., number of exterior walls, number of windows, wall dimensions, window dimensions, area of the building, building material, geographic location, and/or other characteristics), its intended use (e.g., residential, office space, retail space, and/or other intended uses), and desired conditions within the building (e.g., comfort, efficiency of energy usage, and/or other conditions). For example, design of an HVAC system may involve selecting HVAC equipment of an appropriate size for a space, designing a duct system for the space for air distribution, and identifying opportunities to modify building structure materials (e.g., windows, insulation, and/or other materials). Each of these aspects of designing the HVAC system need to take into account characteristics of the building, intended use, and desired conditions within the space in order to design an HVAC system that is suitable for the space.

HVAC system design involves processes of varying degrees of complexity and utility in designing aspects of an HVAC system. The processes may involve various load calculations in order to determine an HVAC system design. One example set of processes that may be performed as part of designing an HVAC system are MANUAL J, MANUAL D, and MANUAL S processes that have been certified by the AIR CONDITIONING CONTRACTORS OF AMERICA (ACCA). Typically, a contractor who needs to perform these processes to design an HVAC system outsources their performance to a third party firm, performs them manually by hand, or uses a software application to perform the processes.

The inventors have recognized that conventional techniques of performing HVAC system design processes (e.g., MANUAL J, MANUAL D, and MANUAL S processes) are time consuming for a contractor and add complexity to the design process. Conventional techniques involve a contractor obtaining information about a space in a building from various different sources and/or making manual measurements (e.g., of wall and window dimensions). The contractor would then use the collected information to perform HVAC system design processes or otherwise have another firm perform the processes. The contractor would then obtain results of the HVAC system design processes, and then use the results to determine an HVAC system design proposal for the building. When a contractor performs the processes (e.g., by hand or using software) it is time consuming to collect the requisite information and then use it correctly in the processes. Moreover, conventional techniques are susceptible to errors and mistakes when performed manually. Even if the contractor were to use conventional software to perform the processes, the inventor would need to manually capture the required information, enter it into a software application, and then use the software application to obtain results of the processes. The contractor subsequently needs to use the results to develop an HVAC system design his/herself. Although a contractor may outsource performance of the design processes to a specialized firm, this introduces additional costs in the HVAC system design.

To address the shortcomings in conventional techniques of HVAC system design, the inventors have developed a system that allows a user (e.g., a contractor) to efficiently design an HVAC system for a space in a building (e.g., a floor home) using a single device (e.g., a smartphone or tablet). The system integrates the various aspects of designing an HVAC system (e.g., collecting information, performing HVAC system design processes to determine suitable HVAC system properties, and determining an HVAC system design). The system may further automate various aspects of designing an HVAC system such that the user can obtain an HVAC system design for a space much faster (e.g., days faster) than with conventional techniques. In some embodiments, the system may be implemented on a device (e.g., a smart phone or table) that: (1) collects information for use in performing an HVAC analysis; (2) performs the HVAC analysis using the collected information to determine HVAC system properties suitable for a space; and (3) determines an HVAC system design proposal based on the determined HVAC system properties.

The system obtains information needed to perform one or more HVAC system design processes (e.g., MANUAL J, MANUAL D, and/or a MANUAL S process). For example, the system may use one or more sensors (e.g., imaging sensor(s)) of the device to obtain boundary information (e.g., number exterior walls, number of windows, dimensions of exterior walls, dimensions of windows), use a global positioning system (GPS) of the device to determine a geographic location of the building, and/or obtain user input through a GUI presented on the device to obtain information about a space or building. The system may further obtain information about intended use and/or desired conditions in the space through the device (e.g., by providing GUI(s) through which user input indicating the information may be provided). The system may use the obtained information for performance of one or more HVAC design processes (e.g., MANUAL J, MANUAL S, and MANUAL D processes) to determine HVAC system properties (e.g., equipment size(s), equipment type(s), and/or duct design) suitable for the space. The system may use the determined HVAC system properties to determine an HVAC system design proposal, and present the HVAC system design proposal to the user.

MANUAL J, MANUAL S, and MANUAL D processes are HVAC design processes that may be used by some embodiments herein. It should be appreciated that these are example HVAC design processes. Embodiments described herein may use other HVAC design processes in addition to or instead of MANUAL J, MANUAL S, and/or MANUAL D processes. Embodiments described herein are not limited to using any particular type of HVAC design process, as other types of HVAC design processes may be used instead of or in addition to HVAC design processes described herein.

The techniques described herein may be implemented in any of numerous ways, as the techniques are not limited to any particular manner of implementation. Examples of details of implementation are provided herein solely for illustrative purposes. Furthermore, the techniques disclosed herein may be used individually or in any suitable combination as aspects of the technology described herein are not limited to the use of any particular technique or combination of techniques.

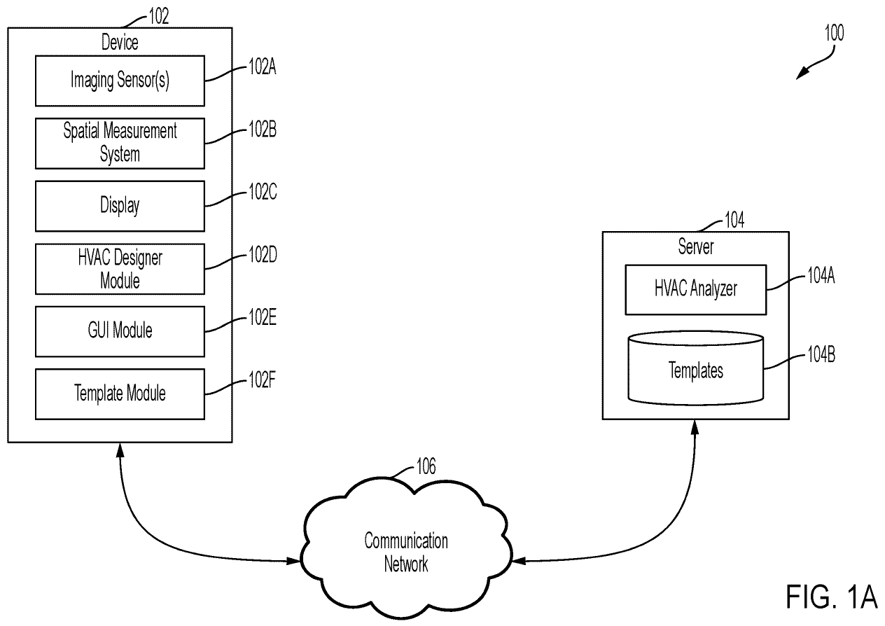

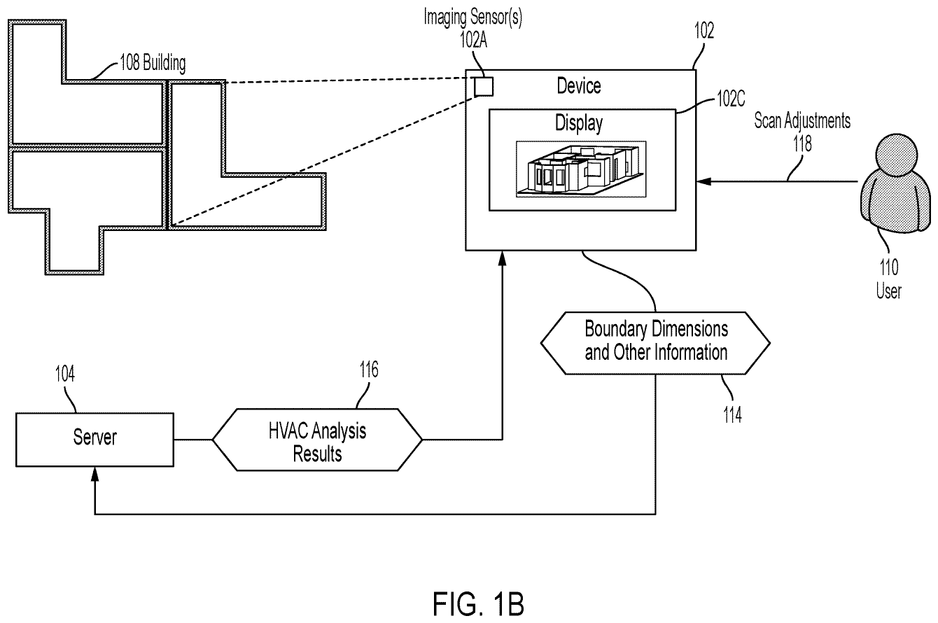

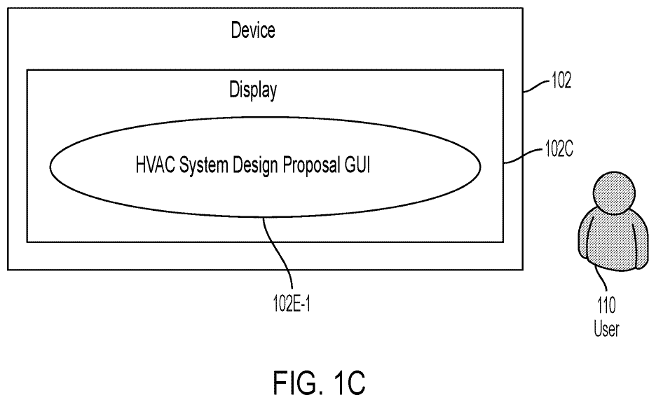

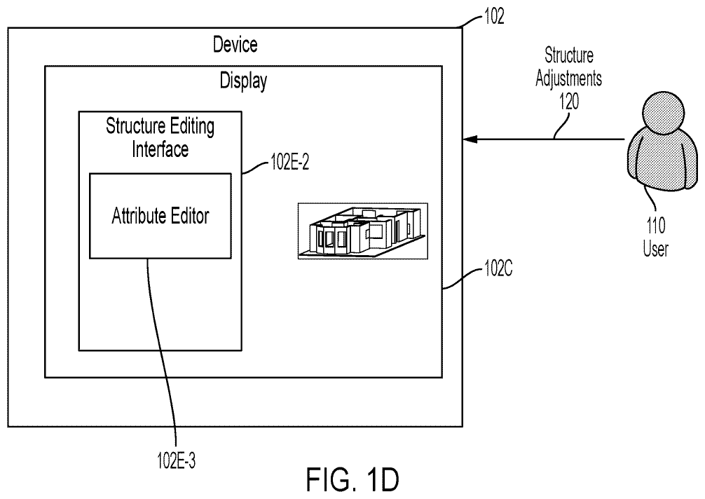

FIG. 1A is an example environment 100 in which some embodiments of the technology described herein may be implemented. The environment 100 includes a computing device 102 and a server 104 configured to communicate through a communication network 106.

The device 102 may be any suitable computing device. In some embodiments, the computing device may be a mobile device (e.g., a smartphone, tablet, laptop, or other suitable mobile device). In some embodiments, the device 102 may be a wearable device (e.g., a smartwatch). In some embodiments, the device 102 may be a component of another device. For example, the device 102 may be embedded in a measurement device used in construction.

The device 102 includes multiple components including imaging sensor(s) 102A, a spatial measurement system 102B, a display 102C, an HVAC system designer module 102D, and a GUI module 102E.

The imaging sensor(s) 102A may obtain spatial measurement data that can be used to determine information about a space. For example, the spatial measurement data may include depth or range measurements performed by the imaging sensor(s) 102A. In some embodiments, the imaging sensor(s) 102A may obtain thermal measurement data. For example, the imaging sensor(s) 102A may obtain measurements of temperature and/or change in temperature in various portions of a space.

In some embodiments, the imaging sensor(s) 102A may include a camera. In some embodiments, the camera may be a digital camera of the device 102. For example, the device 102 may be a smartphone and the camera may be a digital camera of the smartphone. The camera may be configured to capture light through a lens and generate an image (e.g., for capture and/or presentation on the display 102C of the device 102).

In some embodiments, the imaging sensor(s) 102A may include a range sensor that measures variable distance. In some embodiments, the range sensor may be a light detection and ranging (LiDAR) sensor. The LiDAR sensor may: (1) emit a light pulse (e.g., a laser pulses) in an environment of the sensor; (2) detect reflection of the light pulse from a surface in the environment; and (3) determine a time taken for a reflected light pulse to reach the LiDAR sensor. The LiDAR sensor may use the time for the reflected light pulse to reach the LiDAR sensor to determine a distance traveled by the emitted light pulse. In some embodiments, the LiDAR sensor may be used to generate a 3D representation of the environment. The LiDAR sensor may emit multiple light pulses in the environment, and the reflected light pulses may be used to identify boundaries (e.g., walls) from which a 3D representation of the environment may be generated. For example, the device 102 may use the LiDAR sensor to generate a 3D floorplan of a floor in a building. The device 102 may use the floorplan to determine boundary information (e.g., number of walls, number of windows, wall dimensions, window dimensions, door dimensions, and/or other boundary dimensions).

In some embodiments, the imaging sensor(s) 102A may include a thermal imaging sensor. For example, the thermal imaging sensor may be a thermal imaging camera (e.g., an infrared (IR) camera). The thermal imaging sensor may measure temperature differences throughout an environment (e.g., a space in a building). In some embodiments, the thermal imaging sensor may detect thermal energy (e.g., IR energy) and generate an image based on the detected thermal energy to provide a temperature measurement. The thermal imaging sensor may output a temperature based on the detected thermal energy. A thermal imaging sensor may be used by the device 102 to determine temperature in a space of a building.

In some embodiments, the imaging sensor(s) 102A may be embedded in the device. For example, the sensor(s) 102A may include an embedded LiDAR sensor and/or camera of a smartphone. To illustrate, the device 102 may be an APPLE IPHONE and the LiDAR sensor may be part of the APPLE IPHONE. In some embodiments, an imaging sensor of the imaging sensor(s) may be external to the device. For example, the imaging sensor may be an external sensor that is communicatively coupled to the device (e.g., through a wired connection, Bluetooth, near-field communication (NFC), and/or other mechanism).

In some embodiments, the spatial measurement system 102B may determine measurements of different aspects of a space using spatial measurement data obtained from the imaging sensor(s) 102A. In some embodiments, the spatial measurement system 102B may: (1) identify boundaries in the space; and (2) determine dimensions of the boundaries. A boundary may mark a limit of a portion of a space and/or the space. For example, a boundary may be an outline marking a limit of a wall, door, or window. The spatial measurement system 102B may determine dimensions of a boundary using data from the imaging sensor(s) 102A. For example, the spatial measurement system 102B may: (1) identify boundaries of walls, windows, and/or doors using distance information generated by a LiDAR sensor; and (2) determine a measurement of the dimensions using distance information obtained from the LiDAR sensor.

In some embodiments, the spatial measurement system 102B may use augmented reality (AR) in conjunction with a camera and a LiDAR sensor of the device 102 to determine boundary information. The spatial measurement system 102B may provide an AR GUI that guides a user to scan a space such that the spatial measurement system 102B can obtain real time data from a LiDAR sensor, and use the data to identify boundaries and determine their dimensions. The spatial measurement system 102B may scan a space using the camera and LiDAR sensor. In some embodiments, the spatial measurement system 102B may provide an AR GUI that guides a user around the space to obtain data to generate a 3D model (e.g., a 3D floorplan) of the space. The spatial measurement system 102B may use the 3D model to identify boundaries (e.g., walls, windows, and/or doors) and determine boundary dimensions. For example, the spatial measurement system 102B may extract dimension values stored as part of the 3D model.

In some embodiments, the spatial measurement system 102B may use an AR system of the device 102. For example, the spatial measurement system 102B may use the ARKIT platform of an IOS device. The spatial measurement system 102B may use the ROOMPLAN API to obtain a 3D floorplan of a space. The spatial measurement system 102B may obtain information about the space from the 3D floorplan. For example, the spatial measurement system 102B may obtain boundary dimensions, space size (e.g., square footage), number of walls, number of windows, and/or other information from the 3D floorplan. As another example, the spatial measurement system 102B may use the ARCORE platform of an ANDROID device to obtain boundary dimensions, space size, number of walls, number of windows, and/or other information.

In some embodiments, the spatial measurement system 102B may allow a user of the device 102 to adjust a 3D model (e.g., a 3D floorplan) generated from scanning a space using the imaging sensor(s) 102A. The spatial measurement system 102B may allow the user to adjust properties of structures in the space. In some embodiments, the spatial measurement system 102B may provide a GUI (e.g., using the GUI module 102E) through which a user can provide input to adjust a 3D floorplan. The GUI may display a 3D floorplan and allow the user to edit the 3D floorplan. For example, the GUI may allow a user to modify dimensions of structures (e.g., windows, walls, and/or doors) in the space. As another example, the GUI may allow a user to add in new structures (e.g., new windows, walls, and/or doors) into the 3D model of the space. In some embodiments, the GUI may allow a user to provide input using various gestures. For example, the GUI may allow a user to select a structure by applying a touch input (e.g., on a touch screen) or a click input (e.g., using a mouse) on the structure in the 3D floorplan for a period of time (e.g., 1 second, 1.5 seconds, 2 seconds, or another suitable period of time) and providing input to adjust the structure. For example, the user may drag a point on the selected structure to adjust its position (e.g., by adjusting its location in the 3D model), dimensions (e.g., by scaling the structure size up or down in the 3D model), and/or orientation (e.g., by rotating the structure in the 3D model).

In some embodiments, the spatial measurement system 102B may store parametric representations of structures in a 3D floorplan of a space. A parametric representation of a structure may store information about the structure such as dimensions (e.g., position, orientation, length, width, and/or height). The spatial measurement system 102B may automatically update the parametric representation of the structure in response to user inputs provided through a GUI. When a new structure is added to the 3D model, the spatial measurement system 102B may add a parametric representation of the structure storing its properties (e.g., dimensions, location, and/or orientation). For example, the spatial measurement system 102B may add a new wall to a 3D model obtained from scanning a space. The spatial measurement system 102B may receive input through a GUI indicating a position of the wall within the 3D model, dimensions of the wall, and/or an orientation of the wall. The spatial measurement system 102B may store the configured properties of the new structure in its parametric representation.

In some embodiments, the spatial measurement system 102B may detect boundaries of a 3D floorplan of a space that separate the space from an exterior of the space (e.g., an exterior hull of the space). The spatial measurement system 102B may identify the boundaries by: (1) identifying points in a 3D model that are outside of the space geometry; and (2) a portion of a 3D floorplan that separates the points outside of the space from the points inside the space. For example, the spatial measurement system 102B may identify walls in a 3D floorplan that are a boundary between an exterior and interior of the space. The spatial measurement system 102B may thus not require a user to provide input indicating the boundaries.

In some embodiments, the display 102C may be any suitable type of display. For example, the display 102C may be a light emitting diode (LED) display, a liquid crystal display (LCD), or other suitable type of display. In some embodiments, the display 102C may be an interactive display through which a user of the device 102 may interact with the device 102. For example, the device 102C may be a touchscreen. In some embodiments, the display 102C may display various GUIs generated by the GUI module 102E for determining an HVAC system design. The GUIs may be interactive and allow the user to provide input indicating information for use in determining the HVAC system design. In some embodiments, the display 102C may display an AR interface. The AR interface may guide a user to collect information about a space (e.g., by providing visual feedback to the user in the AR interface to generate a 3D model of the space).

In some embodiments, the HVAC designer module 102D may determine an HVAC system design for a space in a building. The HVAC designer module 102D may perform HVAC analysis to determine various aspects of an HVAC system design. The HVAC designer module 102D may use information from the spatial measurement system 102B to determine an HVAC system design. For example, the HVAC designer module 102D may use boundary statistics (e.g., number of walls, number of windows, total area of walls and/or windows), boundary dimensions, space size, and/or other information determined by the spatial measurement system 102B to determine the HVAC system design. In some embodiments, the HVAC design module 102D may determine the HVAC system design using information in addition to that obtained from the spatial measurement system 102B.

In some embodiments, the HVAC designer module 102D may obtain information about building material of a building, and use the information to determine an HVAC system design. For example, the HVAC designer module 102D may determine a heat resistance of the building material. In some embodiments, the HVAC designer module 102D may determine the heat resistance by obtaining user input indicating the heat resistance (e.g., through a GUI). In some embodiments, the HVAC designer module 102D may determine the heat resistance using thermal imaging (e.g., a thermal imaging camera as described herein).

In some embodiments, the HVAC designer module 102D may obtain information about an environment of a building, and use the information to determine an HVAC system design. For example, the HVAC designer module 102D may determine an ambient indoor temperature (e.g., using a thermometer). As another example, the HVAC designer module 102D may determine an outdoor air temperature (e.g., by accessing weather data for an area in which the building is located).

In some embodiments, the HVAC designer module 102D may obtain information about a building and use the information to determine an HVAC system design for a space in the building. For example, the HVAC designer module 102D may determine an orientation and/or geographic location of the building (e.g., using GOOGLE MAPS or another map database). As another example, the HVAC designer module 102D may determine a home age and/or date of previous renovation (e.g., using a public assessor database and/or a real estate database). As another example, the HVAC designer module 102D may determine information about energy consumption of the building (e.g., using utility bill information and/or other energy consumption information).

In some embodiments, the HVAC designer module 102D may obtain information about internal sources of radiative heat in a space, and determine an HVAC system design for the space based on the internal sources of radiative heat. In some embodiments, the HVAC designer module 102D may determine the internal sources of radiative heat based on user input indicating the sources (e.g., through a GUI). In some embodiments, the HVAC designer module 102D may automatically identify internal sources of radiative heat using a sensor (e.g., a thermal imaging sensor).

In some embodiments, the HVAC designer module 102D may perform the HVAC analysis by performing one or more HVAC system design processes (e.g., the MANUAL J, MANUAL S, and MANUAL D processes). The HVAC designer module 102D may perform the HVAC system design processes using processor(s) and memory of the device 102. In some embodiments, the HVAC designer module 102D may perform the HVAC analysis by obtaining results of HVAC system design processes performed by HVAC analyzer 104A of server 104. The HVAC designer module 102D may: (1) transmit, through the communication network 106, information about the space (e.g., boundary information, location information, orientation information, materials, size, number of windows, number of doors, number of walls, building material information, building environment information, and/or other information) to the server 104; and (2) receive results of one or more HVAC system design processes performed by the HVAC analyzer 104A. Examples of the HVAC system design processes that may be performed by the HVAC designer module 102D and/or the HVAC analyzer 104A of the server 104 are described herein.

MANUAL JA first HVAC design process may be performed to determine heating and cooling loads of a space. An example of such a process is a MANUAL J process or equivalent thereof. The loads may indicate a system size required for the HVAC system design. The loads may account for building construction and materials. For example, the loads may be determined based on fenestration (e.g., windows, glass doors, skylights), opaque panels (e.g., wood/metal doors, above/below grade walls, partition walls, ceilings, and floors), infiltration (e.g., interior and exterior walls, divisions between conditioned and unconditioned space), ventilation, conditioned floor area, cave overhang depth, internal shading, and number of sky lights. The loads may further be determined based on features of the space such as ducts and blowers, a number of occupants (e.g., determined based on the number of bedrooms), and heat gain (e.g., based on sensible and latent heat gain). The first process may comprise determining the loads based on location of the space. For example, the first process may comprise determining the loads based on geographic location (e.g., city and state), outdoor design temperatures, indoor design temperatures, and orientation. To illustrate, the first process may involve determining a load using equation 1 below.

$$Load = U * A * delta ( T ) \qquad Equation ( 1 )$$

In Equation 1, U is a heat transfer performance index indicating how well a material transfers heat, A is a surface area (e.g., of a wall, window, door, ceiling, or other surface), and delta(T) is the temperature difference across the surface. In some embodiments, a load may be determined in British thermal unit per hour (BTU/h).

A second HVAC design process may be performed by heating and cooling loads determined from performance of the first process to select appropriate equipment for a space. An example of such a process is a MANUAL S process or equivalent thereof. The second process many involve determining a type of HVAC equipment required (e.g., energy and airflow requirements), capacity (e.g., sensible, latent, and total capacity), load sizing limits, and equipment blower information (e.g., external statistic pressure and/or airflow requirements). Equipment meeting the performance requirements may then be identified by performing a look up using performance data obtained from manufacturers.

A third process may be performed to determine a duct design for an HVAC system design. An example of such a process is a MANUAL D process or equivalent thereof. The third process involves determining the longest circulation path that may take place in the system (also referred to as the “critical path”). The HVAC system needs to supply sufficient volume and velocity for the critical path. The third process involves determining a pressure drop per 100 feet, and selecting a suitable fan to provide sufficient velocity. A duct design may be determined to accommodate fan pressure. The third process may involve determining an external static pressure (ESP) based on an airflow requirement (e.g., in cubic feet per minute (CFM)) determined from the third process. The ESP may be determined using a friction analysis by obtaining blower performance data to determine whether the fan will produce a specified air and static pressure. Device pressure losses may be estimated using a series of lookup tables for components such as a heat exchanger, filters, UV lights, supply outlets (e.g., drops across a return, grille, and damper). Summing the device pressure losses together provides a component pressure loss. The available static pressure (ASP) may then be calculated by subtracting the component pressure loss from the ESP. The total effective length (TEL) is then calculated by Equation 2 below.

$$TEL = Supply Side TEL + Return Side TEL \qquad Equation ( 2 )$$

The friction rate may then be determined as ASP*100/TEL. Using a duct slide, the determined CFM and friction rate provide values for sizing ducts (e.g., for round or rectangular ducts) and provide an associated velocity in feet per minute (FPM). Velocity may be compared to the design CFM with limits for turbulence and noise control. The third process may be performed to determine an air distribution system design. The air distribution system design may include a branch lead size determined based on design CFM, friction rate, and duct material used. The air distribution system design may include a trunk size that accommodates the supply branch leads. The air distribution system design may include a return trunk duct velocity that is sufficient to meet lower return air velocity requirements. The air distribution system design may further indicate a return air path that verifies that each room has an open air path. Outputs of the third process may include filters for the HVAC system, grills (e.g., registers), branches into supply registers, and dampers.

The HVAC designer module 102D may determine an HVAC system design proposal using results of the HVAC analysis (e.g., results obtained from performance of the MANUAL J, MANUAL S, and MANUAL D processes). The results of the HVAC analysis may include HVAC system properties that are suitable for a given space. The HVAC designer module 102D may identify HVAC systems (e.g., equipment and/or a duct system) with the properties. In some embodiments, the HVAC designer module 102D may determine an HVAC system design comprising of equipment size(s) and type(s) identified from performing the HVAC analysis (e.g., equipment determined from performance of the MANUAL J and S processes). In some embodiments, the HVAC designer module 102D may determine an HVAC system design comprising of a duct system identified from performing the HVAC analysis (e.g., from performance of the MANUAL D process).

In some embodiments, the HVAC designer module 102D may determine multiple HVAC system designs to propose to a user. For example, the HVAC designer module 102D may determine two, three, four, five, six, seven, or more HVAC system designs to propose to the user. In some embodiments, the number of HVAC system designs that the HVAC designer module 102D is to determine using results of HVAC analysis may be a configurable value. For example, the HVAC designer module 102D may determine one, two, three, or four HVAC system designs according to a user input specifying the configurable value (e.g., through a settings menu of an application GUI). The HVAC designer module 102D may determine multiple HVAC system designs by: (1) determining HVAC system properties (e.g., equipment size, equipment type, duct sizing and length, and/or other characteristics) suitable for a space by performing the HVAC analysis; and (2) identifying multiple HVAC systems with the properties. In some embodiments, the HVAC designer module 102D may: (1) access one or more external databases (e.g., HVAC equipment manufacturer database(s) and/or performance database(s)) storing information (e.g., specifications) about HVAC system systems; and (2) identify HVAC systems in the external database(s) based on desired characteristics (e.g., determined from HVAC analysis). In some embodiments, the HVAC designer module 102D may select HVAC system equipment of different levels of quality to present as different HVAC system designs. For example, the HVAC designer module 102D may select equipment of different levels of efficiency (e.g., in terms of seasonal energy efficiency ratio (SEER)) for different HVAC system designs.

In some embodiments, the HVAC designer module 102D may determine HVAC system designs of different levels of quality. For example, the HVAC designer module 102D may determine HVAC system designs of two, three, or four different levels. To illustrate, the HVAC designer module 102D may determine a “good”, “better”, and “best” levels of HVAC system design. In some embodiments, the different levels of HVAC system designs may be indicated by price. For example, the highest level (e.g., the “best”) may be the most expensive while the lowest level (e.g., “good”) may be the cheapest design. A user may select from the different levels. The HVAC designer module 102D may determine and present information about the design of each level. For example, the HVAC designer module 102D may determine cost information, efficiency, fuel type, applicable incentives, a description for each HVAC system design, estimated energy savings, return on investment, and/or payback period to a homeowner. The HVAC designer module may present the information to a user through a GUI allowing the user to select from among the multiple different levels of HVAC system designs.

In some embodiments, the HVAC designer module 102D may determine pricing information for each HVAC system design. The HVAC designer module 102D may determine a price of an HVAC system design using a database of equipment costs (e.g., in a manufacturer database(s)). For example, the HVAC designer module 102D may use a third-party application program interface (API) to access a firm's price book.

In some embodiments, the HVAC designer module 102D may allow a user (e.g., a contractor) to provide input for an HVAC system design. The HVAC designer module 102D obtain user input (e.g., through a GUI) indicating materials (e.g., pipes, refrigerants, etc.) required to complete installation. In some embodiments, the HVAC designer module 102D may suggest installation materials based on features of the building and/or results of HVAC analysis. In some embodiments, the HVAC designer module 102D may allow a user to edit any aspect of an HVAC system design determined by the HVAC designer module 102D. For example, the HVAC designer module 102D may allow a user to modify aspects of an HVAC system design that were automatically determined using results of HVAC analysis. In some embodiments, the HVAC designer module 102D may allow a user to indicate add-ons to an HVAC system design. For example, the HVAC designer module 102D may allow a user to add features such as a dehumidifier, air sealing, and/or other features that can be added to an HVAC system design. In some embodiments, the HVAC system design module 102D may learn preferences of a user (e.g., a contractor) over time, and make suggestions for aspects of an HVAC system design based on the user's preferences.

In some embodiments, the HVAC designer module 102D may identify one or more incentives (e.g., rebate(s)) that apply to an HVAC system design. The HVAC designer module 102D may access a repository (e.g., a website) storing information about one or more rebates. The HVAC designer module 102D may determine if any of the rebate(s) is applicable to an HVAC system design determined by the module 102D. For example, the HVAC designer module 102D may determine if equipment in a design qualifies for any of the rebate(s) (e.g., based on efficiency, energy usage, and/or other criteria).

In some embodiments, the GUI module 102E may generate various GUIs that may be presented on the display 102C of the device 102. The GUIs may allow a user of the device 102 to interact with the HVAC designer module 102D. In some embodiments, the GUI module 102E may generate one or more GUIs for obtaining information about a space in a building and/or about the building itself. For example, the GUI module 102E may generate a GUI to guide a user using an AR interface of the device 102 to obtain spatial measurement data (e.g., for use in determining boundary dimensions) in a space. As another example, the GUI module 102E may generate GUIs that allow a user to enter information about a space (e.g., image(s), size, boundary dimensions, number of windows, number of doors, number of walls, sources of heat within the space, building material, and/or other information). In some embodiments, the GUI module 102E may generate one or more GUIs that allow a user to modify aspects of an HVAC system design and/or add on features to the HVAC system design. In some embodiments, the GUI module 102E may generate one or more GUIs that allow a user to provide input indicating information about a space (e.g., desired comfort level, health and air quality, energy use, and/or desired system attributes) for use in determining an HVAC system design. In some embodiments, the GUI module 102E may allow a user to add notes about a space and/or an HVAC system design through a GUI. In some embodiments, the GUI module 102E may generate one or more GUIs presenting HVAC system design(s) to a user. The GUI(s) may allow selection of an HVAC system design for a respective space in a building.

In some embodiments, the template module 102F may define templates of spaces (e.g., homes). A template may specify information that may be used by the HVAC designer module 102D in performing HVAC system design process(es) (e.g., that are performed by the HVAC designer module 102D). The information specified by the template may include information about attributes of different structure categories (e.g., window, wall, door, ceiling, floor, and/or a skylight) that may be found in a space. In some embodiments, the template may specify, for each structure category, values of attributes associated with the structure category. Table 1 below lists example information that may be included in a template for various structure categories.

TABLE 1

| Structure | |
|---|---|
| Category | Information About Structures |
| Walls | Wall Type |
| | Primary Structure |
| | Other Construction Type |
| | Block Core |
| | Framing Material |
| | Frame Construction |
| | Cavity Insulation |
| | Board Insulation |
| | Exterior Finish |
| | Interior Finish |
| | Insulation Depth |
| | ASTM R-Value |
| | Average Thickness |
| | Facing and Thickness |
| Windows | Window Type |
| | NFRC Rated |
| | Glass Type |
| | Operability |
| | Number of Panes |
| | Emissivity |
| | Window Frame |
| | Frame Construction |
| | Surface Topology |
| | Partition Screen |
| | Surface Coating |
| | Storm Window |
| Doors | Door Material |
| | Door Core |
| | Has Storm |
| | NFRC Rated |
| | Glass Type |
| | Number of Panes |
| | Emissivity |
| | Window Frame |
| Ceilings | Ceiling Type |
| | Deck Construction |
| | Attic Ventilation |
| | Attic Fan |
| | Radiant Barrier |
| | Roofing Material |
| | Roof Color |
| | Insulation Type |
| | Insulation R-Value |
| Floors | Floor Type |
| | Basement or Crawl Space Wall Insulation |
| | Radiant Floor Heat |
| | Space Leakage |
| | Floor Insulation |
| | Floor Cover |
| | Soil Condition Below Floor |
| | Slab Insulation Arrangement |
| | Slab Insulation R-value |
| | Width of Shortest Slab Side |
| Skylights | Panel Shape |
| | Number of Panes |
| | Glass Type |
| | Type of Plastic |
| | Curb Type |
| | Sash Construction |
| | Curb and Light Shaft Construction |

In some embodiments, the template module 102F may generate a template by: (1) obtaining user input through a GUI that defines the template; and (2) transmitting the template to the server 104 through the communication network 106 for storage by the server 104 (e.g., in datastore 104B). For example, the GUI module 102E may generate a GUI on the display 102C of the device 102 through which a user may provide information (e.g., as described in Table 1) that is stored in a template. The template module 102F may generate the template using the information provided. For example, the template module 102F may generate a data structure including multiple different fields storing the information about different structures. The template module 102F may store the data structure as a template.

In some embodiments, the template module 102F may load a previously generated template (e.g., to populate information about structures in a space). For example, the template module 102F may load a template to specify default construction properties of structures in a space for which an HVAC system is to be defined. In some embodiments, the template module 102F may load the template by: (1) accessing the template from the server 104 (e.g., from datastore 104B); and (2) using the template to set properties of structures in a given space (e.g., by populating parameter values using information from the template). As an illustrative example, the template module 102F may use information to set construction material parameters for structures in a space for which the HVAC designer module 102D is to perform HVAC system design processes.

In some embodiments, the server 104 may be a computer system separate from the device 102. The server 104 may host one or more services and/or applications on a single or multiple devices. In some embodiments, the server 104 may provide service to multiple devices. Although the example of FIG. 1A shows only device 102, the server 104 may be in communication with one or more other devices not shown in FIG. 1A. For example, the server 104 may perform HVAC system design processes for multiple devices. In some embodiments, the server 104 may be a cloud based server. The cloud based server may comprise of a pooled set of resources (e.g., computing devices and storage hardware) that can be accessed and used on demand by multiple devices. The cloud based server may be located remotely from the device 102.

As shown in FIG. 1A, the server 104 includes an HVAC analyzer 104A. The server 104 may obtain information from the device 102 (e.g., through communication network 106). The HVAC analyzer 104A may use the information to perform HVAC analysis. In some embodiments, the HVAC analyzer 104A may perform HVAC system design processes. The HVAC analyzer 104A may use information obtained by the device 102 (e.g., boundary information, building material information, building environment information, and/or other information) to perform the HVAC system design processes. Examples of HVAC system design processes that may be performed are described herein. The server 104 may transmit, through the communication network 106, results of HVAC analysis performed by the HVAC analyzer 104A to the device 102. The device 102 may use the results of the HVAC analysis to determine one or more HVAC system designs for the space.

As shown in FIG. 1A, the server 104 includes a datastore 104B storing templates (e.g., generated by the template module 102F). The templates may include template(s) designed by a user of the device 102 and/or templates defined by other user(s) of other device(s). In some embodiments, the datastore 104B may store a crowdsourced collection of templates defined by various users. In some embodiments, a user may be granted access to a subset of the templates stored in the datastore 104B. For example, the user may be granted access to a subset of templates created by an organization that the user is affiliated with. As another example, the user may be granted access to templates by creators or the templates. As another example, the user may be granted access to templates according to a role of the user designated in the system.

Although the illustrative embodiment of FIG. 1A shows the computing device 102 and the server 104 as separate entities, in some embodiments, the computing device 102 and server 104 may be implemented in a single device (e.g., the device 102). In some embodiments, the HVAC analyzer 104A may be a component of the device 102 and/or functionality of the HVAC analyzer 104A may be incorporated into the HVAC system designer module 102D. In such embodiments, information may not be exchanged through the communication network 106. In some embodiments, the device 102 may be configured to perform functionality of the server 104 and components thereof described herein.

In some embodiments, the device 102 may utilize a hybrid approach. The device 102 may have the server 104 perform operations when the device 102 has connectivity to the server 104 (e.g., through a network). When the device 102 is unable to communicate with the server 104 (e.g., due to a weak signal strength), the device 102 may perform the operations described herein with respect to the server 104. In some embodiments, the device 102 may suspend certain operations until communication with the server 104 is re-established. In some embodiments, the device 102 may perform operations by itself when communication with the server 104 is not re-established after a threshold amount of time.

The communication network 106 of FIG. 1A may be the Internet, a local area network (LAN), a wide area network (WAN), and/or any other suitable communication network. Some embodiments are not limited in this respect.

Although FIG. 1A shows a single device 102, in some embodiments, the components 102 may be implemented on multiple devices. For example, a smartphone and a table may implement one or more of the components. The smartphone may be used to scan a space to generate a 3D floorplan and a tablet may use the 3D floorplan to determine an HVAC system design. In this example, the smartphone may execute the imaging sensor(s) 102A and spatial measurement system 102B to obtain the 3D floorplan, while the tablet may execute the HVAC designer module 102D to determine an HVAC system design.

FIG. 1B is an example interaction among the entities of FIG. 1A to determine an HVAC system design proposal, according to some embodiments of the technology described herein. As shown in FIG. 1B, a user 110 is using the device 102 to capture information about a space in the building 108. The building 108 may be a residential building (e.g., a home), commercial building (e.g., an office), or other type of building (e.g., manufacturing facility, storage facility, etc.). The space may be any portion of the building 108. For example, the space may be the entire building 108, a floor of the building 108, or one or more rooms within the building 108. In the example of FIG. 1B, the space is a floor of the building 108.

The device 102 may use the imaging sensor(s) 102A to obtain spatial measurement data for the space. For example, the imaging sensor(s) 102A may obtain depth or range data that the device 102 uses to generate a 3D floorplan of the space. The 3D floorplan being generated may be shown on the display 102C of the device 102. As described herein, the user 110 may be presented with an AR interface in the display 102C that guides the user around the space to capture measurement data which the spatial measurement system 102B uses to generate the 3D floorplan.

In some embodiments, the spatial measurement system 102B may use spatial measurement data to determine information in addition or instead of generation of a 3D model (e.g., a 3D floorplan). For example, the spatial measurement system 102B may determine a size of the space (e.g., square footage) and boundary dimensions (e.g., wall dimensions, window dimensions, and/or door dimensions). As another example, the spatial measurement system 102B may determine a number of windows, doors, walls and/or other structures in the space. As yet another example, the spatial measurement system 102B may identify which walls form a boundary between the building 108 and an environment outside the building 108. Such walls may also be referred to as “exterior walls”. In some embodiments, the spatial measurement system 102B may store information within a 3D floorplan generated by the spatial measurement system 102B. In some embodiments, the spatial measurement system 102B may store the information independent of a 3D floorplan generated by the spatial measurement system 102B.

The device 102 may additionally or alternatively obtain information user input from the user 110 indicating information about the building 108 or space. For example, the device 102 may generate one or more GUIs through which the user 110 may provide input indicating information about the building 108 or space. In some embodiments, the device 102 may generate GUI(s) through which the user 110 may provide input indicating considerations for the HVAC system design such as images, boundary dimension input or modification, number(s) of exterior walls, number(s) of windows, desired comfort, desired health and air quality, a source of energy use, and/or desired attributes for the HVAC system design.

As shown in FIG. 1B, in some embodiments, the device 102 may receive input 118 to adjust a 3D model of the building 108. As described herein with reference to the spatial measurement system 102B, the scan adjustments 118 may modify a 3D model of the building 108 (e.g., a 3D floorplan of the building 108). The scan adjustments 118 may modify one or more structures (e.g., window(s), wall(s), door(s), and/or other structure(s)) in the 3D model, or add additional structure(s) to the 3D model. In some embodiments, the display 102C may provide a touch screen interface through which a user can provide the scan adjustments 118 by tapping, holding, and/or dragging. For example, a user may tap and hold a structure for a period of time to enable editing options in a GUI displaying the 3D model. The user may then rotate the structure, change its position, and/or resize the structure. As another example, the user may select a new structure to add to the 3D model from a menu of structures. The user may position the new structure in the 3D model, set its orientation and/or dimensions.

In some embodiments, the device 102 may perform additional processing using a 3D model of the building 108. For example, the device 102 may perform additional processing to identify an exterior hull of the building 108. The device 102 may identify the exterior hull by identifying walls of the building 108 that mark a boundary between an interior of the building 108 and the exterior of the building 108. The device 102 may store an indication of the exterior hull of the building 108 (e.g., for use in performing one or more HVAC system design processes).

As shown in FIG. 1B, the device 102 transmits the collected information 114 to the server 104. The information 114 may include boundary dimensions and other information. The device 102 may transmit the information 114 through the communication network 106 (e.g., the Internet). After receiving the information 114, the server 104 may perform HVAC analysis. The server 104 may perform the HVAC analysis by performing one or more HVAC system design processes (e.g., MANUAL J, MANUAL S, and/or MANUAL D processes) to determine characteristics (e.g., specifications) of an HVAC system that would be suitable for the space in the building 108. The server 104 transmits the HVAC analysis results 116 to the device 102. The device 102 may use the HVAC analysis results 116 to determine one or more HVAC system designs to present to the user 110 via the display 102C as described herein with reference to FIG. 1A.

FIG. 1C is an example presentation of an HVAC system design proposal on the device 102 of FIG. 1A, according to some embodiments of the technology described herein. As shown in FIG. 1C, the device 102 shows in the display 102C a GUI 102E-1 presenting an HVAC system design proposal to the user 110. The GUI 102E-1 may include a graphical display of information about one or more HVAC system designs such as cost, efficiency, fuel type, applicable incentives, and/or a system description. The GUI 102E-1 may further allow the user 110 to provide input indicating an instruction to send the HVAC system design proposal (e.g., to a customer). Example GUIs for displaying an HVAC system design proposal are described herein.

FIG. 1D is an example presentation of an interface 102E-2 that allows editing attributes of structures in a 3D floorplan of a space, according to some embodiments of the technology described herein. The structure editing interface 102E-2 may allow the user 110 to set and/or adjust the construction properties of structures in a space. In some embodiments, the structures in a 3D model of building 108 generated by device 102 may each have associated attributes. The attributes may include information about the structure such as construction material, insulation, emissivity, and/or other information. Example attributes that may be stored by the device 102 for various structures are shown in Table 1 above. The structure editing interface 102E-2 may allow a user to select a structure in a 3D model of building 108 shown on display 102C (e.g., by tapping or clicking on the structure). The structure editing interface 102E-2 may, in response to the selection of a structure, display an attribute editor 102E-3 in the display 102C through which the user 110 can provide input.

As shown in FIG. 1D, the structure editing interface 102E-2 includes an attribute editor 102E-3 through which user 110 can provide input to set attributes of a selected structure. In some embodiments, the attribute values may be pre-populated (e.g., from a template). The attribute editor 102E-3 may allow the user 110 to adjust pre-populated values of the attributes. In some embodiments, the attribute editor 102E-3 may display current values of attributes of the selected structure. The attribute editor 102E-3 may allow the user 110 to modify the current values. For example, the user 110 may select an attribute and change the value of the attribute (e.g., by entering the value and/or selecting the value from a predetermined list of candidate attribute values).

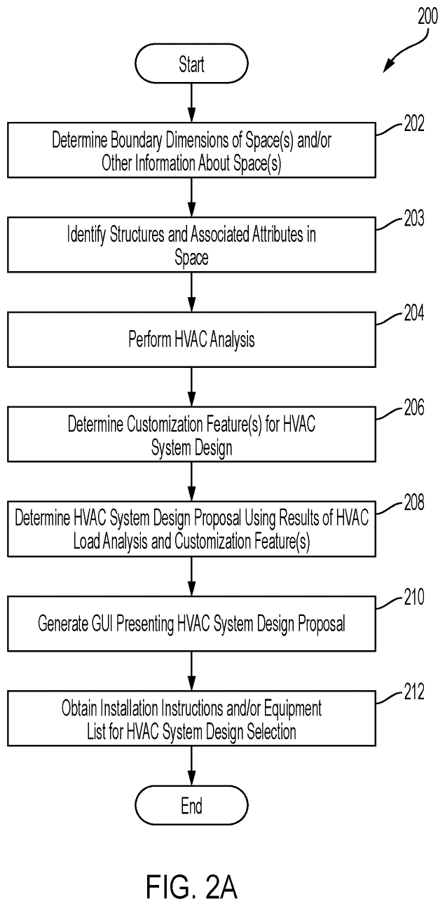

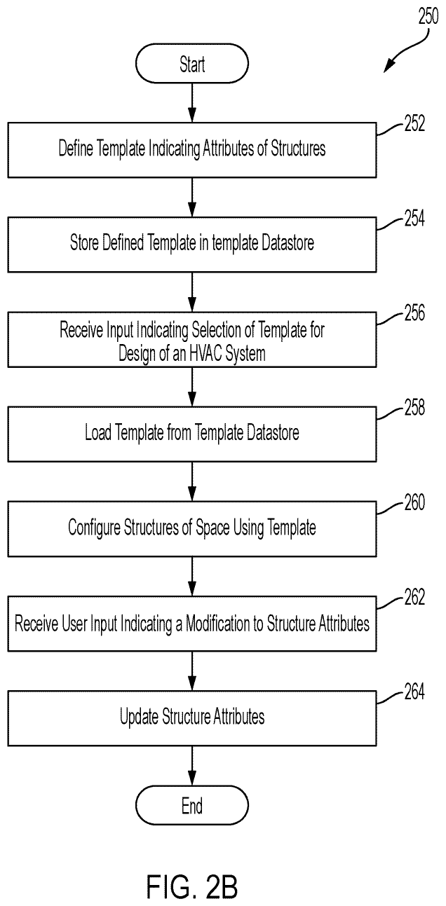

FIG. 2A is an example process 200 of determining an HVAC system design proposal for one or more spaces in a building, according to some embodiments of the technology described herein. Process 200 may be performed by device 102 described herein with reference to FIGS. 1A-1C. The space(s) in the building may comprise of one or more rooms, an entire floor, or other portion of the building.

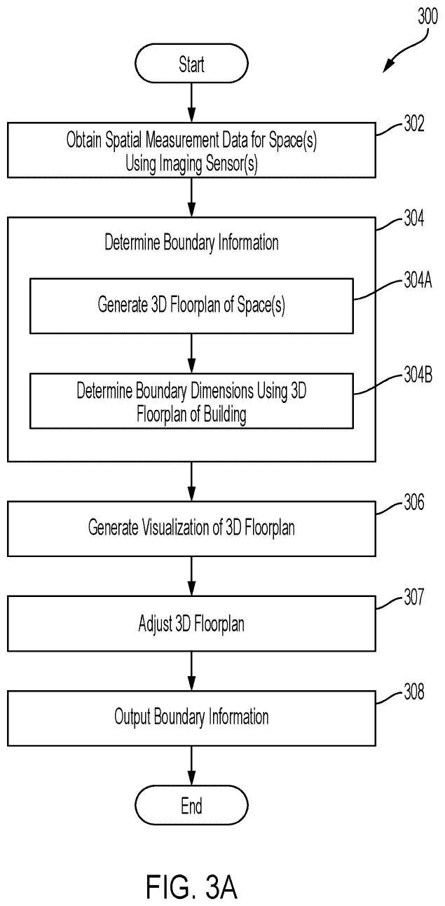

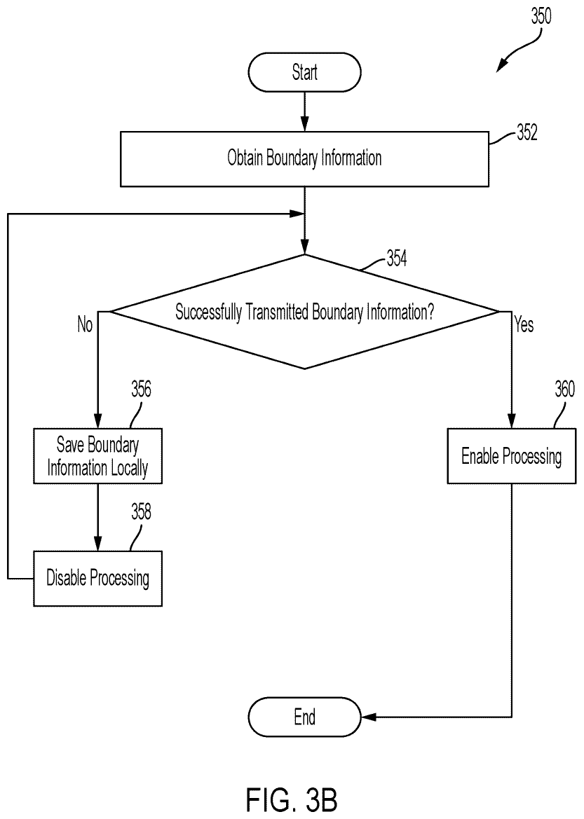

Process 200 begins at block 202, where the system determines boundary dimensions (e.g., of walls, windows, and/or doors) of the space(s). In some embodiments, the system may determine boundary dimensions of the space(s) using imaging sensor(s) (e.g., a camera and/or a LiDAR sensor). For example, the system may generate a 3D model (e.g., a 3D floorplan) using spatial measurement data obtained by the imaging sensor(s), and determine boundary dimensions from the 3D floorplan. The system may determine dimensions of walls, windows, and/or doors in each room from the 3D floor plan. In some embodiments, the system may determine boundary dimensions using the spatial measurement data by processing image(s) of the space(s) to determine the boundary dimensions. For example, the system may perform image processing on an image of a room to determine dimensions of walls, windows, and/or doors in the image of the room. In some embodiments, the system may determine boundary dimensions by generating one or more GUIs through which a user may provide boundary dimensions. For example, the GUI may allow the user to specify a number of walls (e.g., exterior walls) and windows in a room and dimensions of the same. An example process for determining boundary dimensions is described herein with reference to FIG. 3A.

The system may obtain other information about the building and/or space(s) in addition to the boundary dimensions. For example, the system may determine a geographic location and/or orientation of the building (e.g., using a map database). As another example, the system may determine temperature conditions of the building (e.g., by measuring ambient temperature inside the building using a thermometer and/or obtaining temperature data about an environment outside of the building). As another example, the system may detect heat sources within the space(s) (e.g., using a thermal imaging sensor) or receive input through a GUI specifying heat sources within the space(s). As another example, the system may obtain information about building material of the building (e.g., through user input in a GUI). Other example information that may be obtained by the system are described herein with reference to FIG. 1A.

Next, process 200 proceeds to block 203, where the system identifies structures (e.g., windows, doors, walls, and/or other structure(s)) and associated attributes in the space(s). In some embodiments, the system may identify the structures by automatically identifying the structures in a 3D model of the space(s) obtained at block 202. For example, the system may identify a window by detecting features in the 3D model that represent a window. As another example, the system may identify a wall in the 3D model by detecting features in the 3D model that represent a wall. In some embodiments, the system may identify the structures by receiving user input indicating the structures in the 3D model. For example, the system may receive user input indicating that a particular portion of the 3D model is a wall, window, door, or other structure.

In some embodiments, the system may determine attributes of identified structures. In some embodiments, the system may obtain attribute values as user input. For example, the system may provide a GUI through which a user can input attributes of structures (e.g., construction material). Example attributes of various structures that may be specified are listed in Table 1 above. In some embodiments, the system may populate attribute values from a template (e.g., as part of process 250 described herein with reference to FIG. 2B). The system may automatically set attribute values to values specified in the template. In some embodiments, the system may allow a user to modify attribute values populated from a template (e.g., as described herein with reference to FIG. 1D).

Next, process 200 proceeds to block 204, where the system performs HVAC analysis using the information obtained at block 202 and block 203. In some embodiments, the system may perform the HVAC analysis by performing one or more HVAC system design processes (e.g., MANUAL J, S, and/or D processes). Example HVAC system design processes that may be performed are described herein with reference to FIG. 1A. In some embodiments, the system may perform the HVAC analysis by: (1) transmitting information obtained at block 202 to another system (e.g., server 104); and (2) receiving results of HVAC system design process(es) performed by the other system. The other system may, for example, be a server that the system performing process 200 communicates with through a communication network (e.g., through the Internet). In some embodiments, the system may perform the HVAC analysis by performing the HVAC system design process(es). The system may use its own processor(s) to perform the HVAC system design process(es).

Next, process 200 proceeds to block 206, where the system determines customization features for the HVAC system design. In some embodiments, the system may obtain user input (e.g., through a GUI) indicating the customization features. For example, the system may obtain user input indicating comfort considerations for the HVAC system (e.g., desired humidity or cooling, air quality, energy use, and/or attributes of the HVAC system). As another example, the system may obtain user input indicating add-ons (e.g., humidifier, smart thermostat system, and/or other feature) to include in the HVAC system. As another example, the system may obtain user input indicating services corresponding to the HVAC system (e.g., installation, insulation, duct cleaning, duct sealing, and/or other services).

In some embodiments, the system may automatically determine customization features. For example, the system may determine customization features based on previous selections of a user (e.g., a contractor). As another example, the system may store preferences of a user and determine the customization features for the HVAC system design based on the stored preferences of the user. As yet another example, the system may identify patterns of customization of a user associated with respective HVAC system designs, and determine the customization features based on an identified pattern associated with an HVAC system design determined from results of the HVAC analysis.

Next, process 200 proceeds to block 208, where the system determines an HVAC system design proposal using the results of the HVAC analysis and the customization feature(s). The HVAC system design proposal may comprise of one or more HVAC system designs that the system has determined would be appropriate for the space(s) based on the results of the HVAC analysis and the customization feature(s). For example, the HVAC system design proposal may include HVAC system design(s) that meet the equipment size, equipment type, and air distribution determined from performance of HVAC system design processes. The HVAC system design(s) may further include the customization feature(s) determined at block 206. In some embodiments, the system may determine the HVAC system design(s) by accessing databases (e.g., manufacturer and/or performance databases) storing information about equipment. The system may identify equipment for an HVAC system design that meets characteristics identified from performance of the HVAC system design processes.

In some embodiments, the system may generate multiple different HVAC system designs as part of a proposal. The HVAC system designs may differ in quality (e.g., as indicated by price). For example, the proposal may include a first level HVAC system design that meets the characteristics determined by the HVAC system design processes, a second level HVAC system design that is more efficient, and a third level HVAC system design that is the most efficient. As another example, the proposal may include HVAC system designs of different prices that meet the characteristics indicated by results of the HVAC analysis.

Next, process 200 proceeds to block 210, where the system generates a GUI presenting the HVAC system design proposal to a user of the system. The HVAC system design proposal may be presented to the user in the GUI with information about each HVAC system design included in the proposal. For example, the GUI may include a price, description, and properties of the HVAC system design (e.g., efficiency, fuel type, or type of HVAC system). The GUI may allow the user to select an HVAC system design. For example, the GUI may include a graphical element (e.g., a button) that, when selected, submits a proposal including the selected HVAC system design (e.g., for transmission to a customer or other party).

Next, process 200 proceeds to block 212, where the system obtains installation instructions and/or equipment list for the selected HVAC system design. The system may obtain installation instructions for equipment included in the design (e.g., from a manufacturer database). In some embodiments, the system may obtain a previously stored set of installation instructions and/or equipment list (e.g., from a database of the system performing process 200). The system may transmit the obtained installation instructions and/or equipment list to a device associated with an installation team.

In some embodiments, the system may use information obtained from performing process 200 to automatically fill out forms. For example, certain federal, state, and/or local energy rebates and tax incentives may require filling out of a form to qualify for the incentives. The system may use information obtained from determining a HVAC system design for a space to automatically fill out the form. For example, the system may use results of an HVAC system design process to populate one or more fields of a form. As another example, the system may use information input by a user during determination of the HVAC system design (e.g., during process 200) to populate one or more fields of a form.

FIG. 2B is an example process of using a template in determining an HVAC system design proposal, according to some embodiments of the technology described herein. In some embodiments, process 250 may be performed by the device 102 described herein with reference to FIGS. 1A-1D (e.g., using template module 102F).

Process 250 begins at block 252, where the system defines a template indicating attributes of structures (e.g., doors, windows, walls, and/or other structures). Example attributes that may be indicated by the template are shown in Table 1 above. In some embodiments, the system may generate a GUI through which a user can input information including the attributes of the structures. For example, the GUI may allow the user to specify attribute values for each of multiple structures that may be in a space. The system may generate a data structure storing the attribute values in fields of the data structure.

Next, process 250 proceeds to block 254, where the system stores the defined template in a template datastore (e.g., datastore 104B of the server 104). In some embodiments, the system may transmit the defined template to an external datastore (e.g., managed by a server). For example, the system may transmit the defined template to a repository of templates generated by multiple users. As another example, the system may transmit the defined template to a repository of templates generated by a set of users (e.g., belonging to a particular organization). In some embodiments, the system may store the defined template in memory of the system (e.g., for use in subsequent HVAC system designing performed by the system).

Next, process 250 proceeds to block 256, where the system receives input indicating selection of a template for designing an HVAC system. In some embodiments, the system may provide a GUI presenting multiple templates available to a user of the system. The system may receive, through the GUI, a user input (e.g., a click, tap, or other input) indicating a selection of the template. The selected template may be one that was generated by a user of the system or by another user. In some embodiments, the system may identify which templates that are stored in a datastore the user of the system is permitted to access and present the identified templates in a GUI.

Next, process 250 proceeds to block 258, where the system loads the selected template from the template datastore. In some embodiments, the system may request the template from an external datastore (e.g., by transmitting the request through a communication network). For example, the system may query the external datastore for the selected template. The system may receive the template in response to the request (e.g., through the communication network). In some embodiments, the system may access the template from memory of the system (e.g., if the template is stored in memory of the system).

Next, process 250 proceeds to block 260, where the system configures structures of a space (e.g., a space that was scanned as part of performing process 200 described herein with reference to FIG. 2A). In some embodiments, the system may: (1) identify structures in a 3D model of the space; and (2) configure attributes of the structures using the template. The system may set attribute values of the structure to those specified in the template. For example, the system may set construction properties of walls, doors, and/or windows in the space to properties specified in the template.

Next, process 250 proceeds to block 262, where the system receives user input indicating a modification to attributes of structures in the 3D model of the space. For example, the system may provide a GUI through which the user may adjust attribute values (e.g., as described herein with reference to FIG. 1D). In some embodiments, the system may allow the user to select structures in a 3D model of the space (e.g., obtained by scanning the space using sensors of the system). In response to selection of a structure, the system may provide an editing interface through which the user may adjust attribute values (e.g., as described with reference to FIG. 1D). The system may use the interface to provide input indicating changes to pre-populated attribute values.

Blocks 262, 264 are dashed because, in some cases, a user may not provide any input indicating modifications to structure attributes (e.g., if the user does not want to change the template-specified attribute values). In such cases, the system may not update structure attributes. Thus, process 250 may end without performing the steps at blocks 262, 264.

After process 250 ends, the information about the structures may be used in determining an HVAC system design proposal as described herein with reference to FIG. 2A.

Although process 250 illustrates an example in which a template is defined, and then used by a system, steps in process 250 may be performed by different systems. For example, blocks 252-254 may be performed by one system (e.g., one device) to define a template. Another system (e.g., another device) may then perform blocks 256-264 using the defined template. Blocks 256-264 may be performed for any template that is accessible by the system. Likewise, blocks 2520254 may be performed by any system to generate a new template.

FIG. 3A is an example process 300 of obtaining information about one or more spaces in a building using one or more imaging sensors, according to some embodiments of the technology described herein. Process 300 may be performed by device 102 described herein with reference to FIGS. 1A-1C. In some embodiments, process 300 may be performed as part of process 200 described herein with reference to FIG. 2A. For example, process 300 may be performed as part of block 202 of process 200.

Process 300 begins at block 302, where the system obtains spatial measurement data for the space(s) using the imaging sensor(s). In some embodiments, the system may obtain spatial measurement from a LiDAR sensor. For example, the spatial measurement data may include depth or range measurements of surfaces in the space(s) (e.g., determined by emitting light pulses and measuring a time until detection of reflected light pulses). In some embodiments, the system may obtain spatial measurement data by: (1) capturing image(s) of the space(s); and (2) processing of the image(s) of the space(s) to determine the spatial information measurement data. In some embodiments, the system may capture both an image and LiDAR sensor data, and use both of them in conjunction to obtain the spatial measurement data.

In some embodiments, the system may obtain spatial measurement data by guiding a user of the system with an AR interface. The AR interface may provide the user with guidance and feedback to collect information. For example, the AR interface may provide a visualization of detected boundaries in the space(s) which the system has detected. The user may continue scanning with a system until all the desired surfaces (e.g., walls, windows, doors, and/or other surfaces) have been identified as indicated by the visualization.

Next, process 300 proceeds to block 304, where the system determines boundary information for the space(s). The block 304 includes two subblocks 304A, 304B. At block 304A, the system generates a 3D floorplan of the space(s). Example techniques that may be used by the system to generate the 3D floorplan are described herein with reference to FIGS. 1A-1B. For example, the system may use an XR system to generate the 3D floorplan. The system may use spatial measurement data to generate the 3D floorplan. At block 304B, the system determines boundary dimensions using the 3D floorplan of the space(s). The system may extract dimensions (e.g., of walls, windows, and/or doors) from the 3D floorplan. For example, the 3D floorplan generated by the system may indicate dimensions of various boundaries in the 3D floorplan. The system may obtain the dimensions indicated by the 3D floorplan. In some embodiments, the system may calculate the boundary dimensions from information in the 3D floorplan. For example, the system may calculate the boundary dimensions using lengths and width values indicated by the 3D floorplan.

In some embodiments, the system may determine a number of walls, windows, and/or doors in the space(s) using the 3D floorplan. In some embodiments, the system may determine a size of walls, windows, and/or doors. For example, the system may determine a surface area of a wall, window, or door. In some embodiments, the system may determine a size of the space(s) using the 3D floorplan. For example, the system may determine dimensions of rooms using the 3D floorplan. In some embodiments, the system may identify exterior walls in the space(s) using the 3D floorplan. In some embodiments, the system may determine overall details of the space(s) using the 3D floorplan. For example, the system may determine a total square footage and/or perimeter of the space(s).

Next, process 300 proceeds to block 306, where the system generates a visualization of the 3D floorplan. The system may generate a 3D visualization of the 3D floorplan. In some embodiments, the system may generate a 3D visualization that a user may interact with through a GUI. For example, the GUI may allow the user to rotate a 3D floorplan to view the 3D floorplan from various angles and positions. As indicated by the dotted lines around block 306, in some embodiments, the system may not generate a visualization of the 3D floorplan.

Next, process 300 proceeds to block 307, where the system adjusts the 3D floorplan (e.g., to correct aspects of the 3D floorplan and/or add missing details in the 3D floorplan). In some embodiments, the system may adjust the 3D floorplan by: (1) receiving user input to adjust the 3D floorplan (e.g., through a GUI displaying the 3D floorplan); and (2) adjusting the 3D floorplan based on the user input. For example, the system may adjust the 3D floor plan by modifying one or more structures in the 3D floorplan and/or adding new structure(s) to the 3D floorplan. The system may provide a GUI through which a user may interact with the 3D floor plan and provide input to adjust the 3D floorplan. Example adjustments and how they are performed are described herein with reference to FIGS. 1A and 1B. As indicated by the dashed lines of block 307, in some cases, the system may not adjust the 3D floorplan (e.g., because a user may not provide any user input to adjust the 3D floorplan).

Next, process 300 proceeds to block 308, where the system outputs the boundary information. For example, the system may output the boundary information to an HVAC designer module for determination of an HVAC system design proposal for the space(s) as described herein with reference to FIG. 2A.

FIG. 3B is an example process 350 of transmitting boundary information (e.g., a 3D floorplan) from a device to another system. In some embodiments, the process 350 may be performed by the system that performed process 300 described herein with reference to FIG. 3A. For example, the process 350 may be performed by the device 102 to transmit a 3D floorplan to the server 104, each of which is described herein with reference to FIGS. 1A-1D.

Process 350 begins at block 350, where the system obtains boundary information. The system may obtain boundary information by performing process 300 described herein with reference to FIG. 3A.

Next, process 350 proceeds to block 354, where the system attempts to transmit the boundary information to another system (e.g., an external server). The system may attempt to transmit the boundary information through a communication network (e.g., the Internet). For example, the system performing process 350 may be a mobile device (e.g., a smartphone or tablet) and may attempt to transmit the boundary information through a data connection of the mobile device.

If at block 354 the system is successful in transmitting the boundary information, then process 350 proceeds to block 360, where the system enables additional processing using the boundary information. The additional processing may include, for example, adjusting the 3D floorplan, editing of structure attributes (e.g., constructions materials of structures), and/or triggering one or more HVAC system design processes. After block 360, process 350 ends.

If at block 354 the system is unsuccessful in transmitting the boundary information, the process 350 proceeds to block 356, where the system stores the boundary information locally. The system may store the boundary information in memory of the system. For example, the system may be a smartphone and store the boundary information (e.g., a 3D floorplan) in memory of the smartphone. After saving the boundary information locally at block 356, process 350 proceeds to block 358, where the system disables processing until the boundary information is successfully transmitted. For example, the system may restrict a user from adjusting the 3D floorplan, editing structure attributes (e.g., construction materials of structures), and/or triggering one or more HVAC system design processes. The system may be restricted from performing the processing until the boundary information is successfully transmitted.

After block 358, the process 350 proceeds to block 354, where the system makes another attempt to transmit the boundary information. In some embodiments, the system may periodically attempt transmission. In some embodiments, the system may attempt transmission in response to a user command. In some embodiments, the system may attempt transmission when the system detects connectivity with a communication network (e.g., a wireless data network).

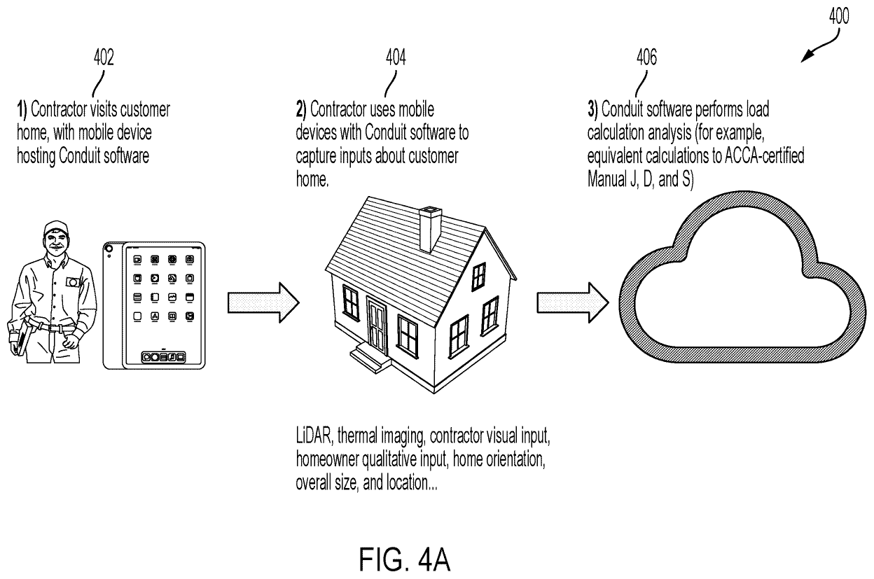

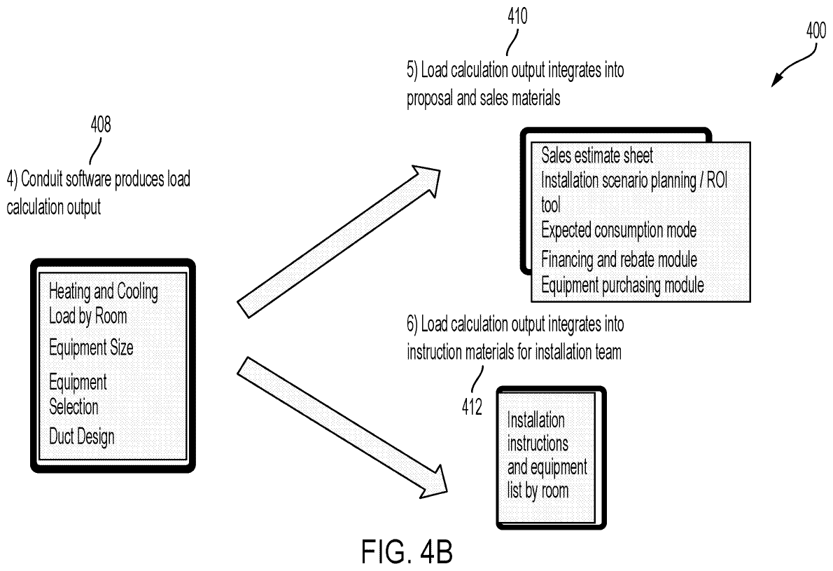

FIGS. 4A-4B illustrate an example sequence 400 of steps for determining an HVAC system design, according to some embodiments of the technology described herein. The steps of FIGS. 4A-4B may be performed in the environment 100 of FIGS. 1A-1B.

At step 402, a contractor may visit a building (e.g., a home) with a mobile device. The mobile device may be device 102 described herein with reference to FIGS. 1A-1B. At step 404, the contractor may use the mobile device to capture information about the home. Example information that may be captured and techniques of capturing the information are described herein. For example, the system may obtain information using a LiDAR sensor, a thermal imaging sensor, input from the contractor, and/or input from the homeowner. Next, at step 406, the device performs HVAC analysis. In the example of FIGS. 4A-4B, the device transmits collected information to a server (e.g., a cloud based server) to perform HVAC design processe(s) (e.g., ACCA-certified MANUAL J, MANUAL D, and MANUAL S processes). In some embodiments, the device may perform the processes.

At step 408 (shown in FIG. 4B), the device obtains results of the HVAC system design processes (e.g., heating and cooling loads, equipment size, equipment type, and/or duct system design). At step 410, the device uses the results to determine an HVAC system design proposal for the home (e.g., as described in process 200 described herein with reference to FIG. 2A). The device may present the HVAC system design proposal to the contractor along with information about HVAC system design(s) included in the proposal. The information may include pricing information and other information about the HVAC system design(s). The results of the HVAC system design processes may further be used for installation planning, forecasting of expected consumption, expected energy consumption identification of financing and rebate, and/or purchase of equipment. At step 412, the device uses the results of the HVAC system design processes to generate installation instructions and indicate an equipment list organized by room.

In some embodiments, the device may use information obtained from performing an HVAC system design to automatically fill out forms. For example, certain federal, state, and/or local energy rebates and tax incentives may require filling out of a form to qualify for the incentives. The device may use information obtained from determining a HVAC system design for a space to automatically fill out the form. For example, the device may use results of an HVAC system design process to populate one or more fields of a form. As another example, the device may use information input by a user during determination of the HVAC system design (e.g., during process 200) to populate one or more fields of a form.

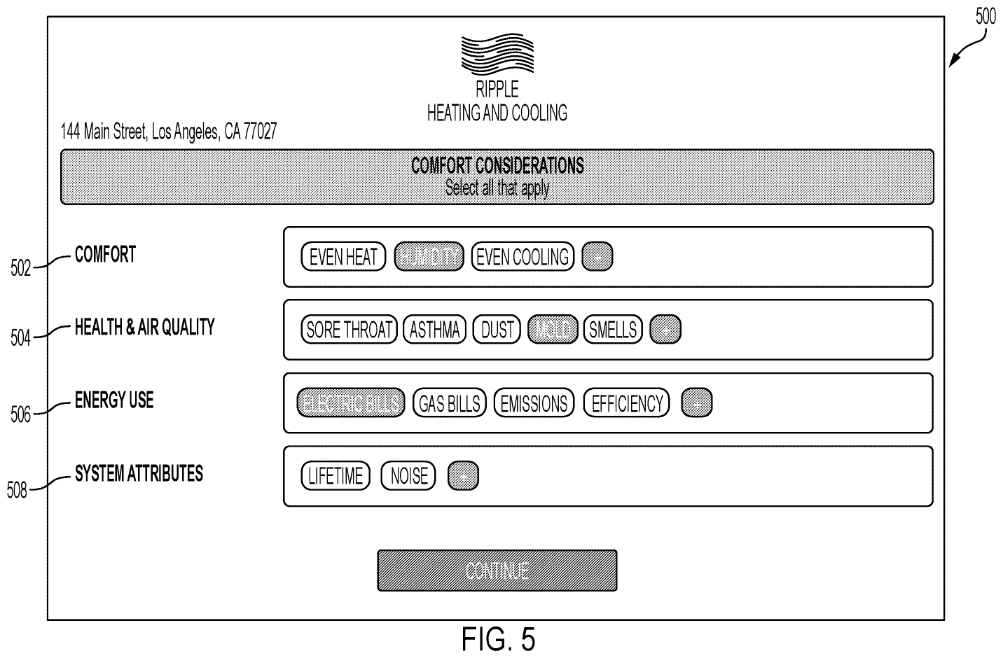

FIG. 5 is an example graphical user interface (GUI) 500 through which a system may receive user input indicating comfort considerations for an HVAC system design, according to some embodiments of the technology described herein. For example, the GUI 500 may be generated by GUI module 102E of device 102 described herein with reference to FIGS. 1A-1C. As shown in FIG. 5, the GUI 500 allows a user to provide input indicating a desired comfort 502. The input may be a selection from a set of options including even heat, humidity, and even cooling. The GUI 500 allows a user to provide input indicating a health and air quality consideration 504. The input may be a selection from a set of options including sore throat, asthma, dust, mold, and smells. The GUI 500 allows a user to provide input indicating a consideration for energy use 506. The input may be a selection from a set of options including electric bills, gas bills, emissions, and efficiency for the system. The GUI 500 allows a user to provide input indicating a consideration of system attributes. The input may be a selection from a set of options including lifetime, and noise of the system.

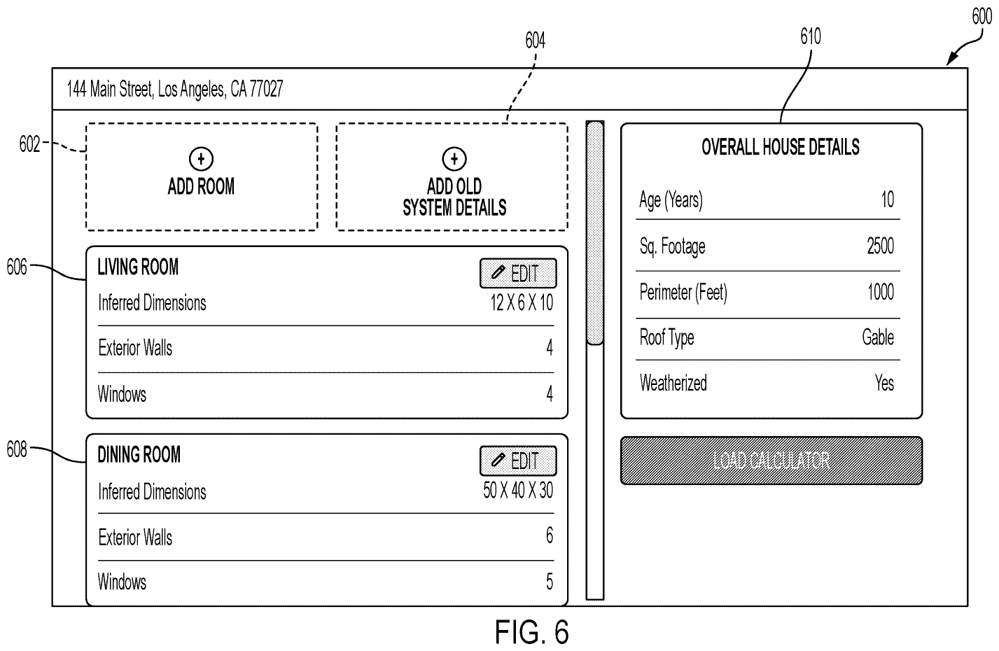

FIG. 6 is an example GUI 600 through which a system may receive user input indicating information about one or more spaces, according to some embodiments of the technology described herein. For example, GUI 600 may be generated by GUI module 102E of device 102 described herein with reference to FIGS. 1A-1C. The GUI 600 includes a graphical element 602 (e.g., a button) that, when selected, allows a user to provide input on another room. The GUI 600 also includes a graphical element 604 (e.g., a button) that, when selected, allows a user to add details about a prior HVAC system. The GUI 600 displays details about various rooms. For example, the GUI 600 includes a section 606 displaying information about a living room such as its inferred dimensions (e.g., from a 3D floorplan or image), number of exterior walls, and number of windows. The GUI 600 also includes a section 608 displaying information about a dining room including its inferred dimensions, a number of exterior walls, and a number of windows. The GUI 600 also includes a section 610 displaying overall details of a house including an age of the house (e.g., determined from a public record database), a square footage, a perimeter, a roof type, and an indication of whether the house is weatherized.

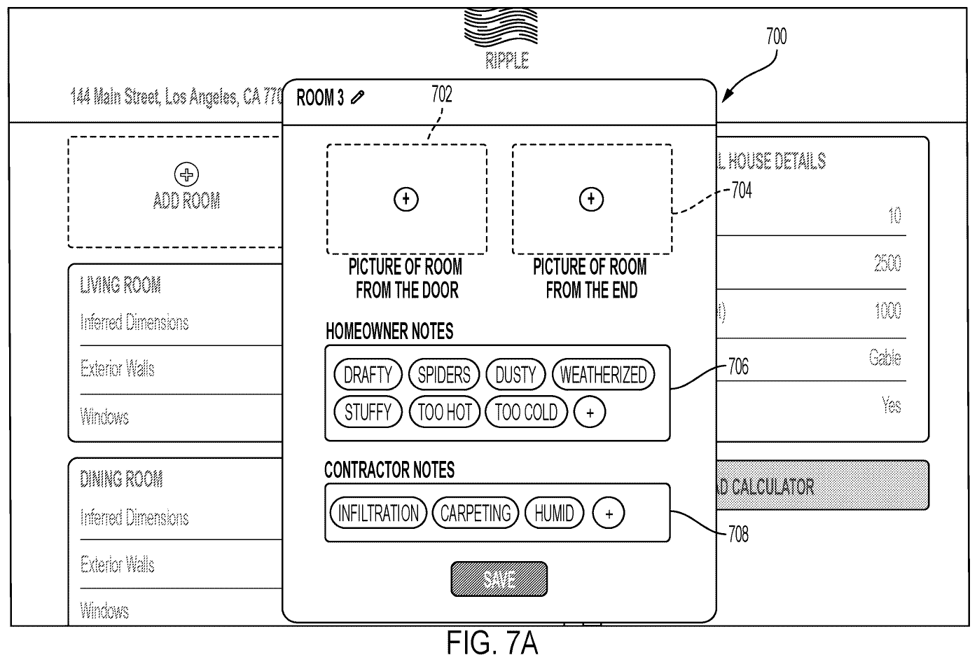

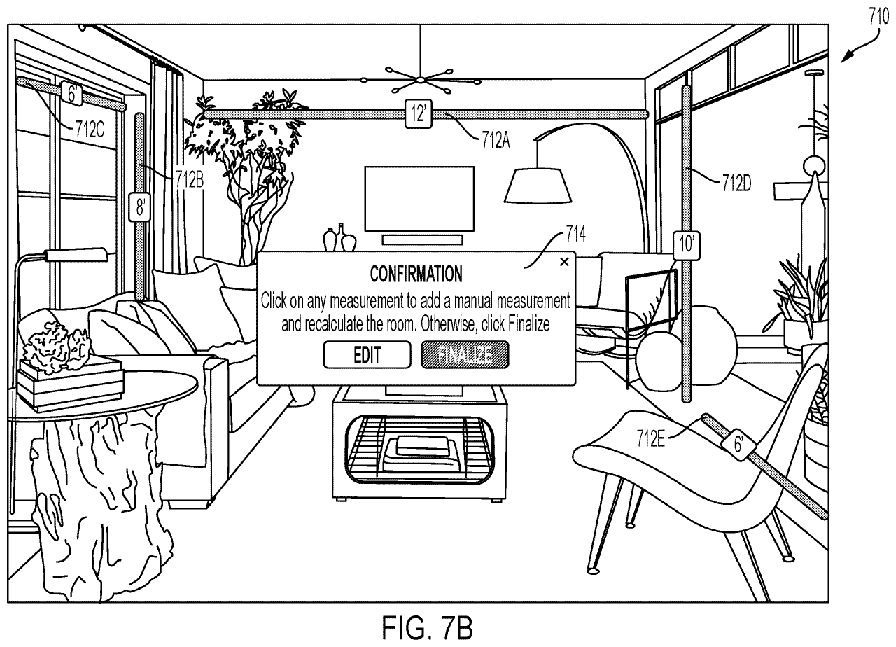

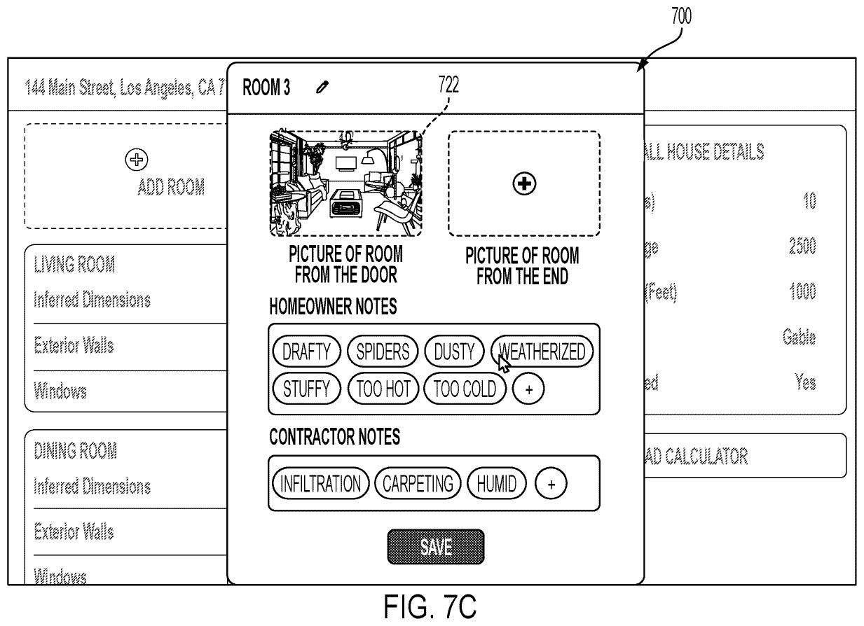

FIGS. 7A-7C illustrate an example GUIs through which a system may receive an image of a space (e.g., a room), according to some embodiments of the technology described herein.

FIG. 7A shows a GUI 700 which includes a graphical element 702 that, when selected, allows a user to capture an image of the room (e.g., using a camera of the device) from the door. The GUI 700 also includes a graphical element 704 that, when selected, allows a user to capture an image of the room from the end. The GUI 700 also includes a section 706 that allows entry of homeowner notes (e.g., indicating whether the room is drafty, stuffy, weatherized, too cold, too hot, or whether there are spiders in the room). The GUI 700 also includes a section 708 that allows entry of contractor notes (e.g., input indicating infiltration, carpeting, and/or humidity in the room).

FIG. 7B shows a GUI 710 that may be displayed for capturing an image (e.g., after selection of graphical elements 702 or 704 form GUI 700). The user has captured an image in which the device has inferred boundary dimensions (e.g., of windows, walls, and/or room limits). The boundary dimensions may be inferred directly form the image or from a 3D floorplan of the room (e.g., generated by the device). The GUI 710 includes a confirmation message 714 requesting user confirmation that the dimensions measurements are correct. The confirmation message 714 provides an option to finalize the measurements or an option to edit the measurements manually.

FIG. 7C shows the GUI 700 of FIG. 7A after capturing the image 722 of the room. As shown in FIG. 7C, the image 722 is a smaller version of the one shown in FIG. 7B embedded in the GUI 700. The image 722 includes the boundary dimensions from FIG. 7B. After entering the information (e.g., images and notes), a user may select the “save” option in the GUI 700 to save the information.

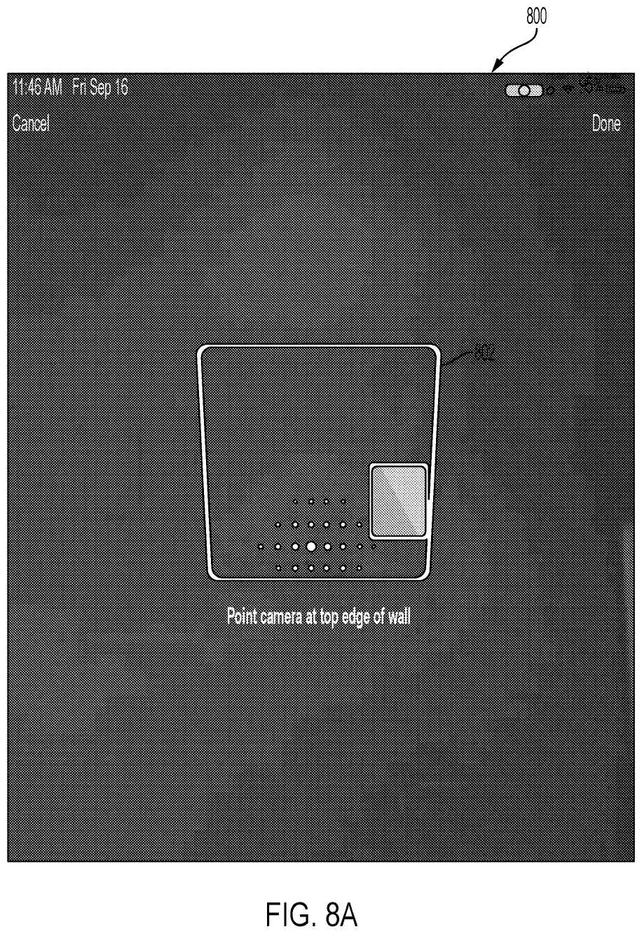

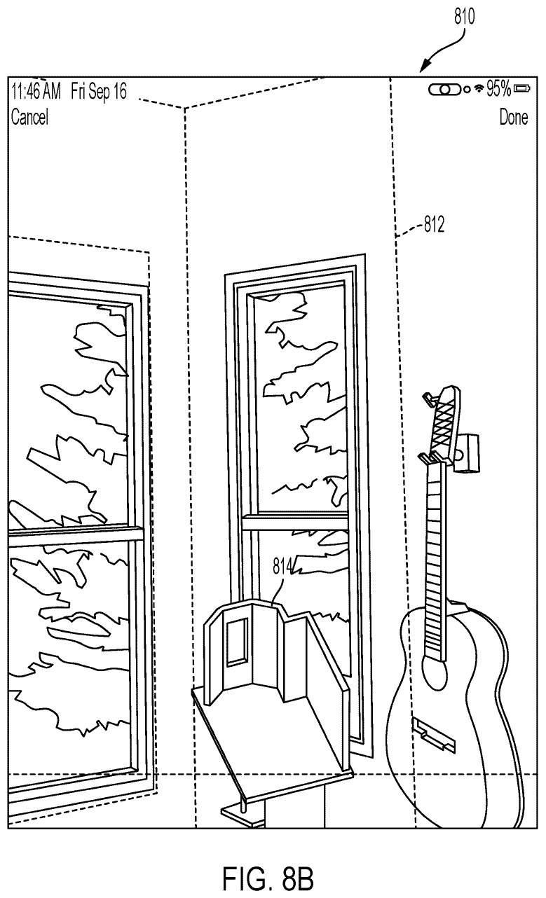

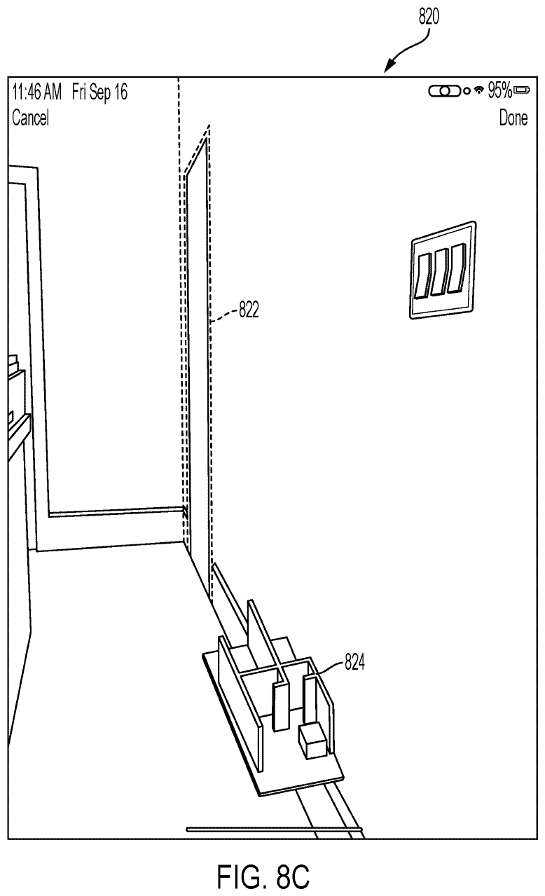

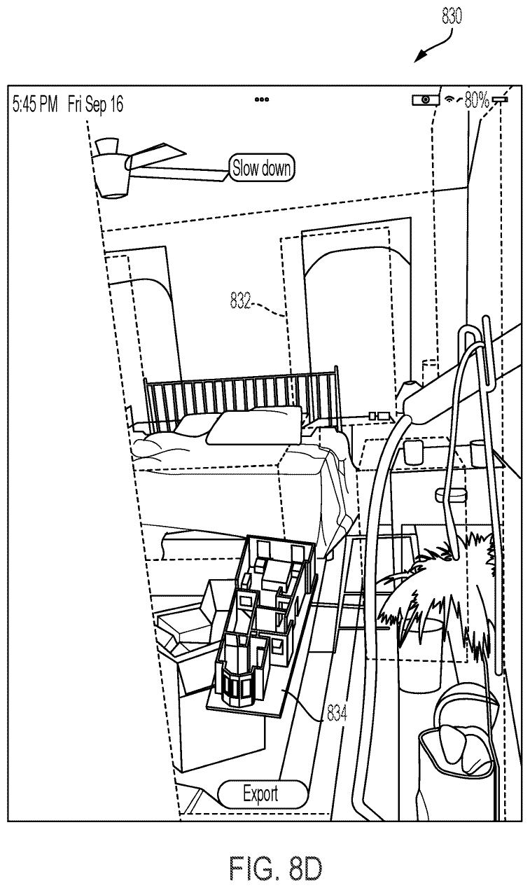

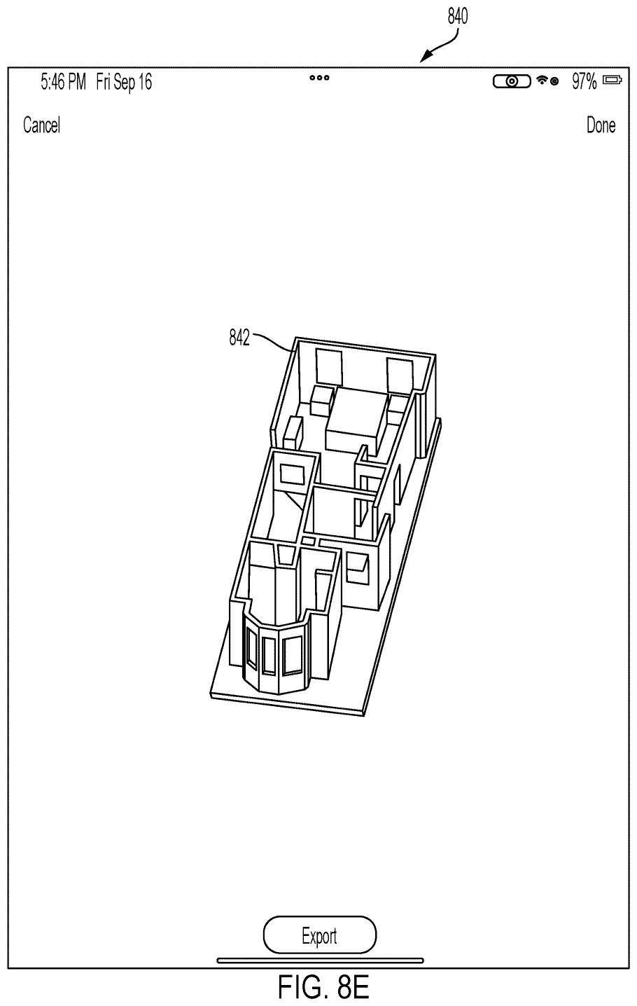

FIGS. 8A-8C illustrate use of imaging sensor(s) of a device to generate a three dimensional (3D) floorplan of a floor in a building, according to some embodiments of the technology described herein. FIGS. 8A-8C show an augmented reality (AR) GUI that may be displayed by the device (e.g., device 102) to guide a user to capture spatial measurement data for generation of the 3D floorplan.

FIG. 8A shows a GUI 800 with a graphical element 802 instructing the user to point the camera at a top edge of the wall. The GUI 800 provides a visualization of a target area of analysis. FIG. 8B shows the GUI 810 in which the user is scanning a portion of a room including windows. As indicated by the lines 812 in the GUI 810, the device is identifying boundaries of the window and mapping them into a 3D floor play 814. FIG. 8C shows a GUI 820 when the user has traversed into a hallway where the device has identified a boundary 812 of a door. The device continues to generate an updated 3D floorplan 824 incorporating the additional spatial measurement data obtained from scanning of the hallway. FIG. 8D shows a GUI 830 when the user has traversed to a bedroom. The device is using spatial measurement data to identify boundaries of various objects in the bedroom including the boundary 832 of a window. The device continues to generate a further updated 3D floorplan 834. FIG. 8E shows a GUI 840 displaying a final 3D floorplan 842 generated by the device. The GUI 840 may allow modifying a view of the 3D floorplan 842 (e.g., by rotating, panning, and/or zooming).

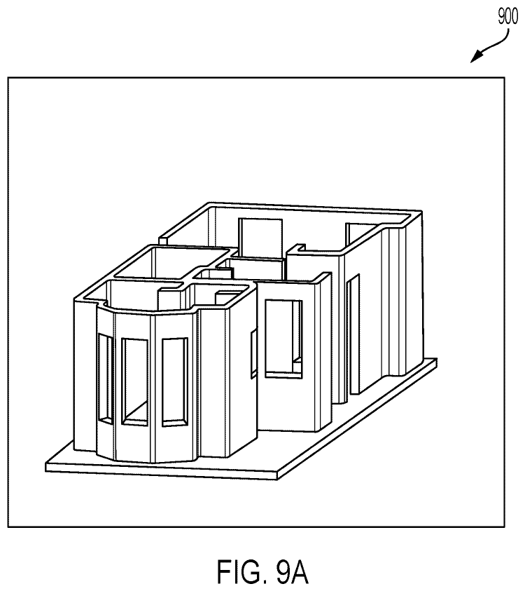

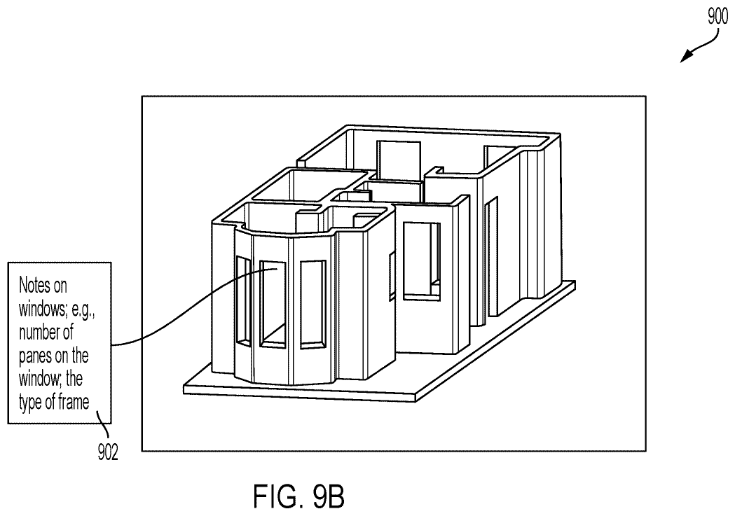

FIG. 9A is an example 3D floorplan 900, according to some embodiments of the technology described herein. The 3D floorplan 900 may, for example, have been generated by the sequence of steps illustrated by FIGS. 8A-8E. As shown in FIG. 9A, the 3D floorplan 900 includes an exterior wall of the floor as well as interior walls. The 3D floorplan further includes spaces for windows throughout the floor. FIG. 9B illustrates association of a user provided note with a portion of the 3D floorplan of FIG. 9A, according to some embodiments of the technology described herein. In the example of FIG. 9B, a user may have selected, in a GUI displaying the 3D floorplan 900, a portion of the 3D floor plan (e.g., a window in the example of FIG. 9B). The user may then provide a note 902 associated with the selected portion of the 3D floorplan. The note 902 may be stored in association with the selected portion of the 3D floorplan. The note 902 may be accessed with the 3D floorplan at a subsequent time.

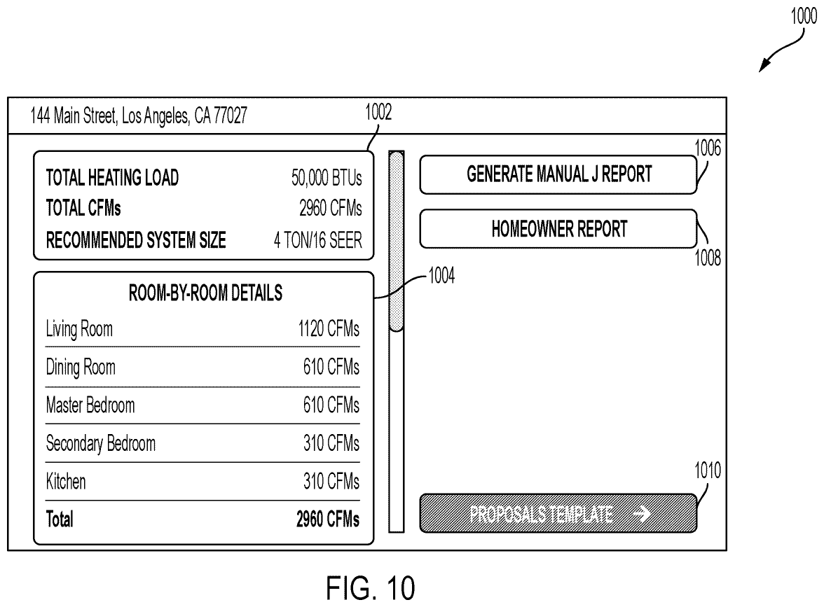

FIG. 10 is an example GUI 1000 displaying results of an HVAC analysis, according to some embodiments of the technology described herein. The GUI 1000 may be generated by device 102 (e.g., after performance of HVAC analysis to obtain results of HVAC system design processes). As shown in FIG. 10, the GUI 1000 includes a section 1002 displaying total load and size values. For example, the section 1002 indicates a total heating load of the home to be 50,000 BTUs, total CFMs of the home to be 2960 CFMs, and a recommended system size of 4 tons/16 SEER. The GUI 1000 further includes a section 1004 showing details of individual rooms. In the example of FIG. 10, the section 1004 displays CFMs for a living room, dining room, master bedroom, secondary bedroom, and kitchen. The GUI 1000 includes a graphical element 1006 (e.g., a button) that, when selected, triggers generation of a MANUAL J report. The GUI 1000 includes a graphical element 1008 (e.g., a button) that, when selected, triggers generation of a homeowner report. The GUI 1000 includes a graphical element 1010 (e.g., a button) that, when selected, triggers display of one or more HVAC system designs of a proposal.

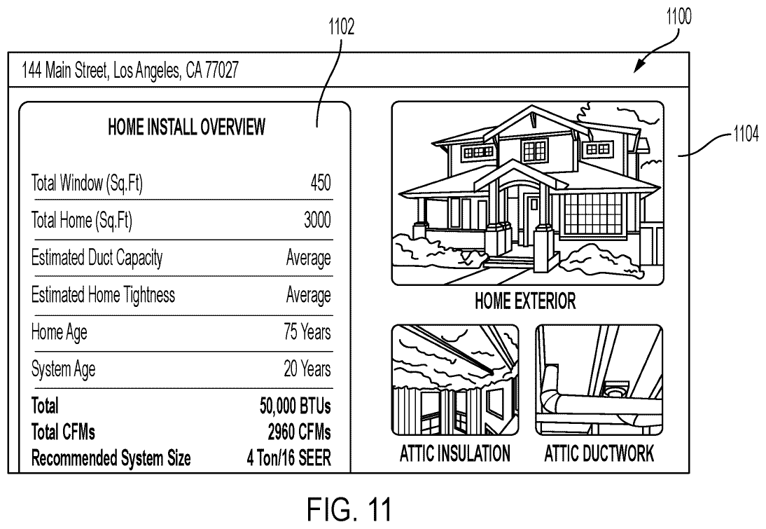

FIG. 11 is an example GUI 1100 displaying results of an HVAC analysis, according to some embodiments of the technology described herein. For example, the GUI 1100 may be generated by the device 102 described herein with reference to FIGS. 1A-1C. The GUI 1100 includes a home install overview section 1102. The section displays information providing an overview of the home with respect to HVAC system. In the example of FIG. 11, the section 1102 shows a total window surface area (in square feet), a total home area (in square feet), an estimated duct capacity, an estimated home tightness, a home age, a system age, a total number of BTUs for the home, total CFMs for the home, and a recommended HVAC system size. The GUI 1100 further includes a section 1104 displaying images of the home.

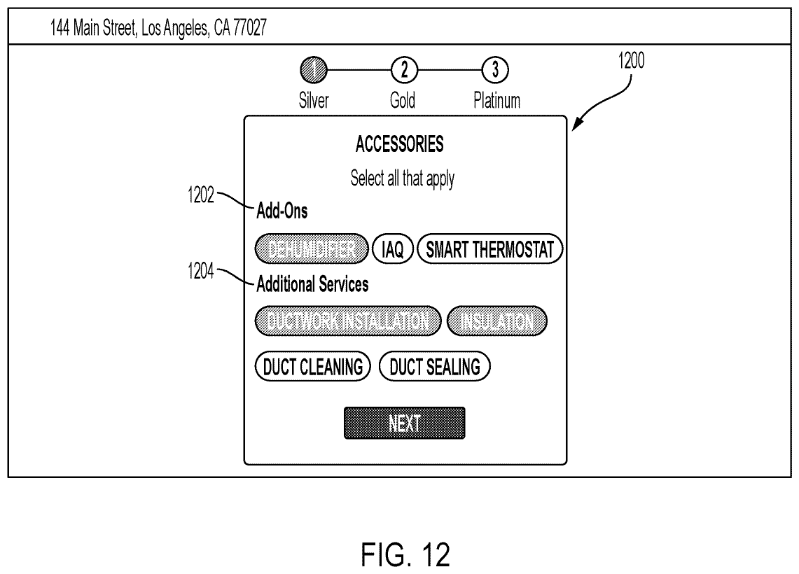

FIG. 12 is an example GUI 1200 through which a system may receive user input indicating features (e.g., accessories) for an HVAC system design, according to some embodiments of the technology described herein. The GUI 1200 may be generated by the device 102 described herein with reference to FIGS. 1A-1C. As shown in FIG. 12, the GUI 1200 allows a user to provide input indicating add-ons 1202 (e.g., a dehumidifier, indoor air quality (IAQ) controller, and/or a smart thermostat system). The GUI 1200 further allows a user to provide input indicating additional services 1204 (e.g., ductwork installation, insulation, duct cleaning, and/or duct sealing). The selections of the accessories may be incorporated in an HVAC system design proposal (e.g., into pricing).

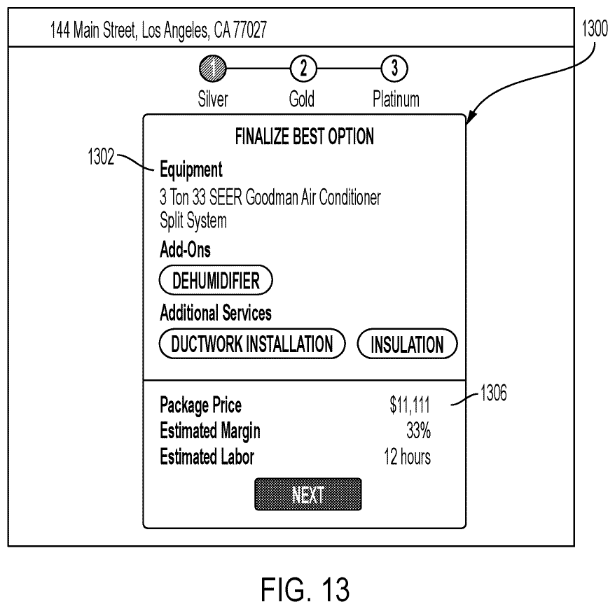

FIG. 13 is an example GUI 1300 displaying an HVAC system design proposal, according to some embodiments of the technology described herein. The GUI 1300 may be generated by the device 102 described herein with reference to FIGS. 1A-1C. The GUI 1300 includes an indication 1302 of equipment in an HVAC system design of the proposal. The GUI 1300 further indicates add-ons and additional services. The GUI 1300 includes a section 1306 indicating a price, estimated margin, and labor time for installation of the HVAC system design.

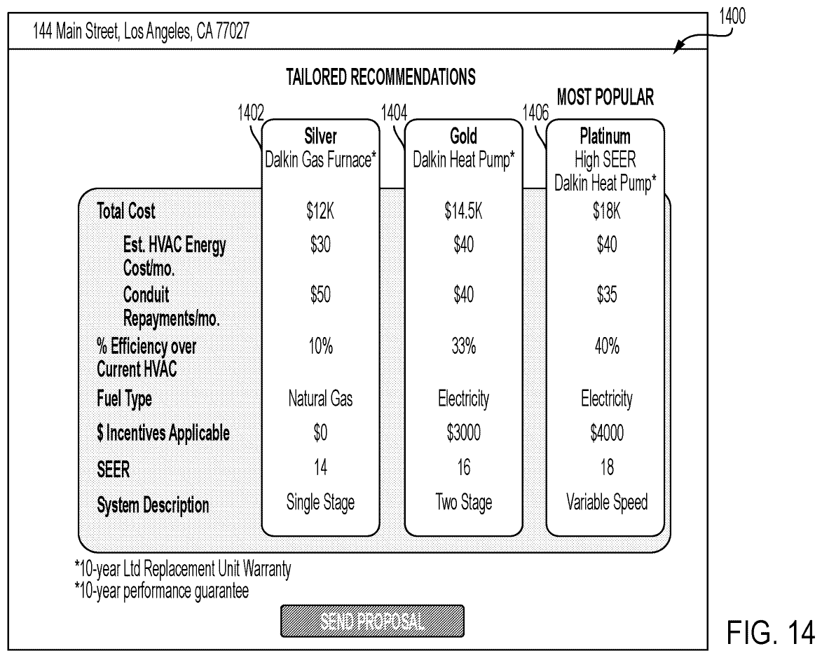

FIG. 14 is an example GUI 1400 displaying an HVAC system design proposal comprising of multiple HVAC system designs that a user may select from, according to some embodiments of the technology described herein. The GUI 1400 may be generated by device 102 described herein with reference to FIGS. 1A-1C. As shown in FIG. 14, the GUI 1400 includes three different levels of HVAC system designs: silver 1402, gold 1404, and platinum 1406. The GUI 1400 includes information for each HVAC system design including total cost, estimated HVAC energy cost per month, repayments to a service provider per month, percentage of efficiency improvement over a current HVAC system, a fuel type of the HVAC system, a monetary amount of incentives available for the HVAC system design, a SEER of the of HVAC system design, and a system description (e.g., single stage, two stage, variable speed, etc.)

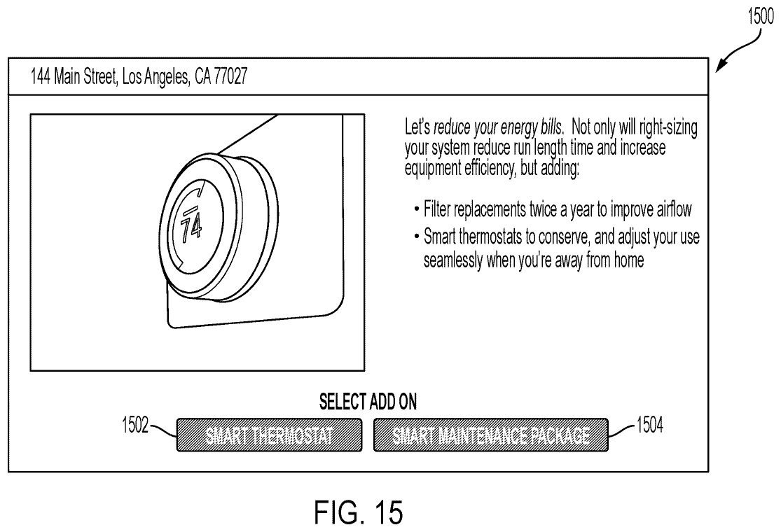

FIG. 15 is an example GUI 1500 through which a system may allow a user to add features to improve energy efficiency, according to some embodiments of the technology described herein. The GUI 1500 may be generated by the device 102 described herein with reference to FIGS. 1A-1C. The GUI 1500 includes a graphical element 1502 that allows a user to add a smart thermostat system to the HVAC system design proposal. The GUI 1500 further includes a graphical element 1504 that allows a user to add a smart maintenance package to the HVAC system design proposal.

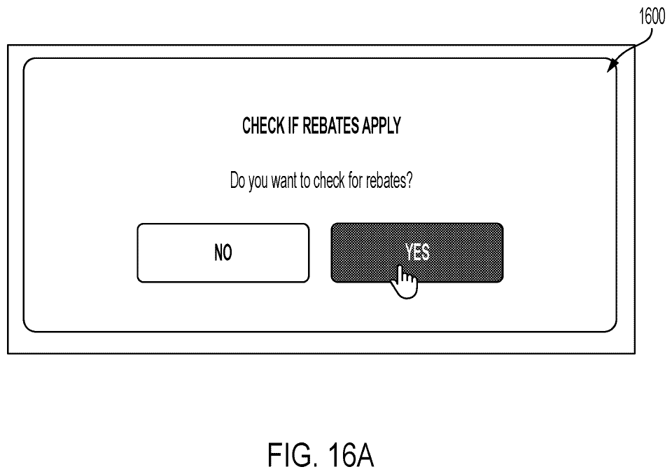

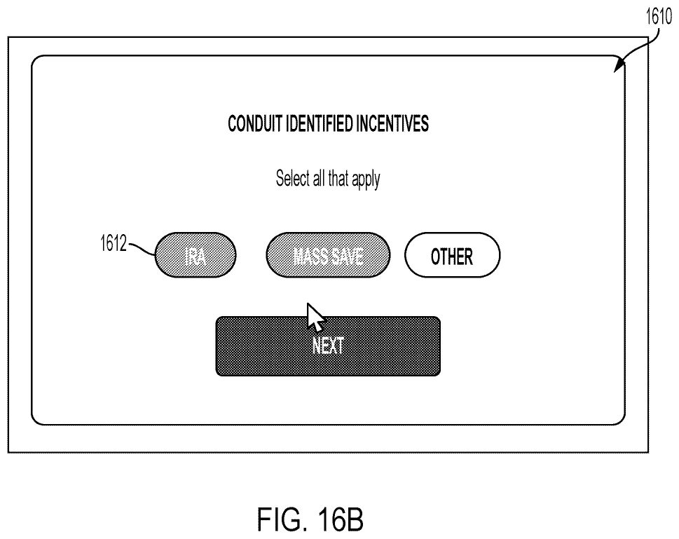

FIGS. 16A-16B illustrate example GUIs for identifying incentives (e.g., rebates) for an HVAC system design, according to some embodiments of the technology described herein. FIG. 16A shows a GUI 1600 requesting user input for the device (e.g., device 102) to check if there are any applicable rebates. The GUI 1600 includes a first option that, when selected, instructs to check whether there are applicable incentives, and a second option that, when selected, instructs to not check for applicable incentives. FIG. 16B shows a GUI 1610 indicating applicable incentives for an HVAC system design. The applicable incentives 1612 indicated in the GUI 1610 are an inflation reduction act (IRA) incentive and a Massachusetts state incentive.

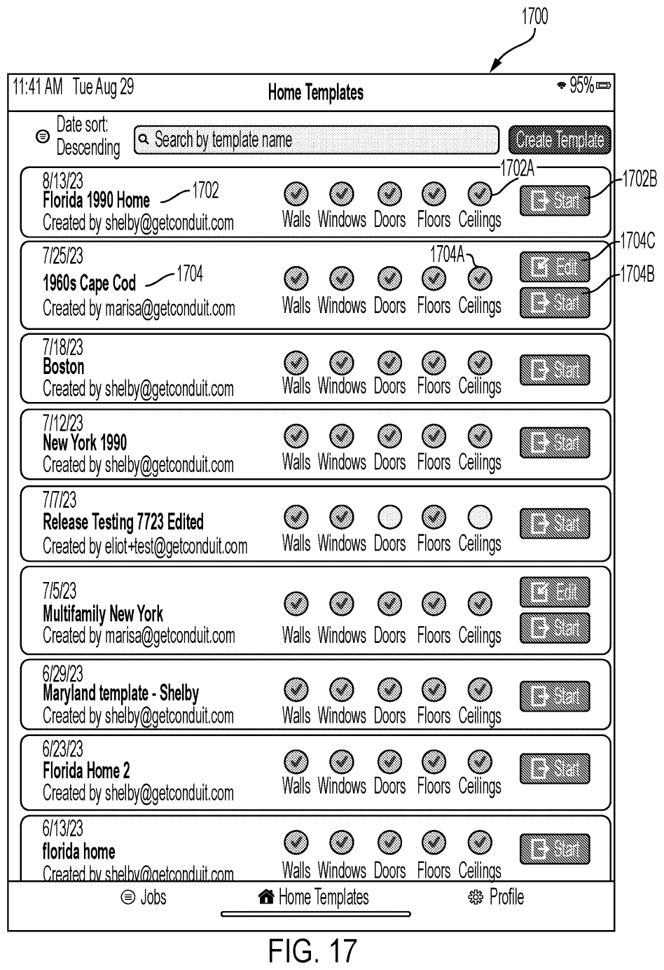

FIG. 17 illustrates an example GUI 1700 displaying a list of templates that may be accessed for determining HVAC system design proposal, according to some embodiments of the technology described herein. The listing of templates in the GUI 1700 includes a template entry 1702 labeled “Florida 1990 Home”. The entry 1702 includes an indication 1702A of which structures the template specifies attribute information for. The indication 1702A indicates that the template specifies attribute values for walls, windows, doors, floors, and ceilings. The entry 1702 includes a selectable graphical element (e.g., a button) 1702B, that when selected, initiates an HVAC system design using the template (e.g., by pre-populating structure attributes using the template). The list of templates further includes a template entry 1704 labeled “1960s Cape Code”. The entry 1704 includes an indication 1704A that the template specifies attribute information for walls, windows, doors, floors, and ceilings. The entry 1704 includes a selectable graphical element 1704C that, when selected initiates an HVAC system design using the template (e.g., by pre-populating structure attributes using the template). The entry 1704 further includes a selectable graphical element 1704C that allows a user to edit the template. For example, selection of the graphical element 1704C may cause the system to generate a GUI through which a user may edit attribute values specified by the template.

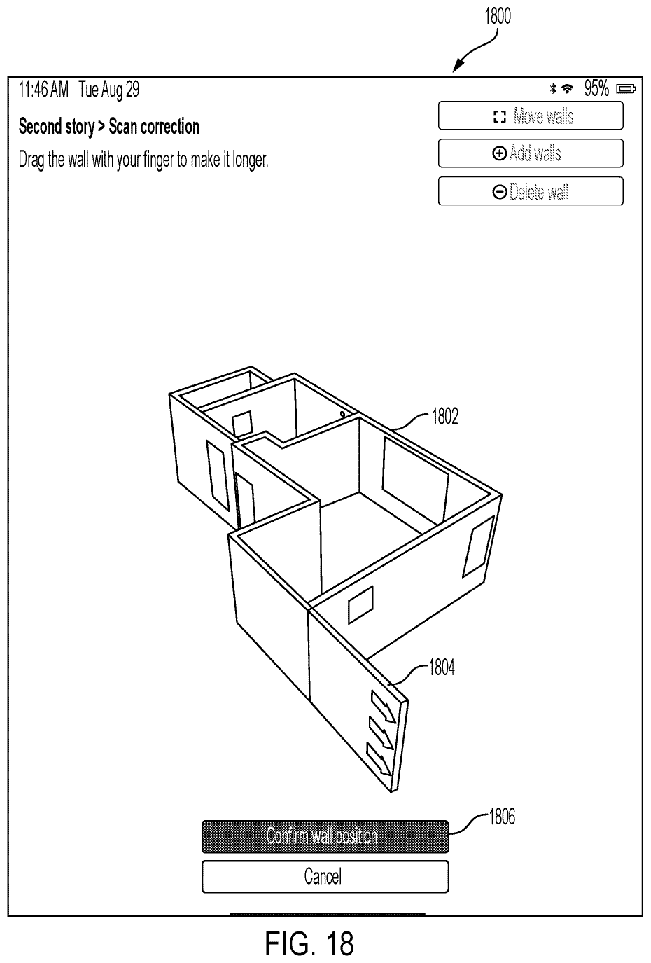

FIG. 18 illustrates an example GUI 1800 for adjusting a 3D model (e.g., a 3D floorplan) obtained from scanning a space, according to some embodiments of the technology described herein. The GUI 1800 shows a 3D floorplan 1802 of a space. In the example of FIG. 18, a user is adjusting the 3D floorplan 1802 by adding an additional wall 1804 to the 3D floorplan. As indicated by the arrows of the wall 1804, the user is extending the wall. The GUI 1800 further includes an option 1806 for the user to confirm an adjustment. The adjustment may be saved as part of the 3D floorplan by the system in response to selection of the option 1806.

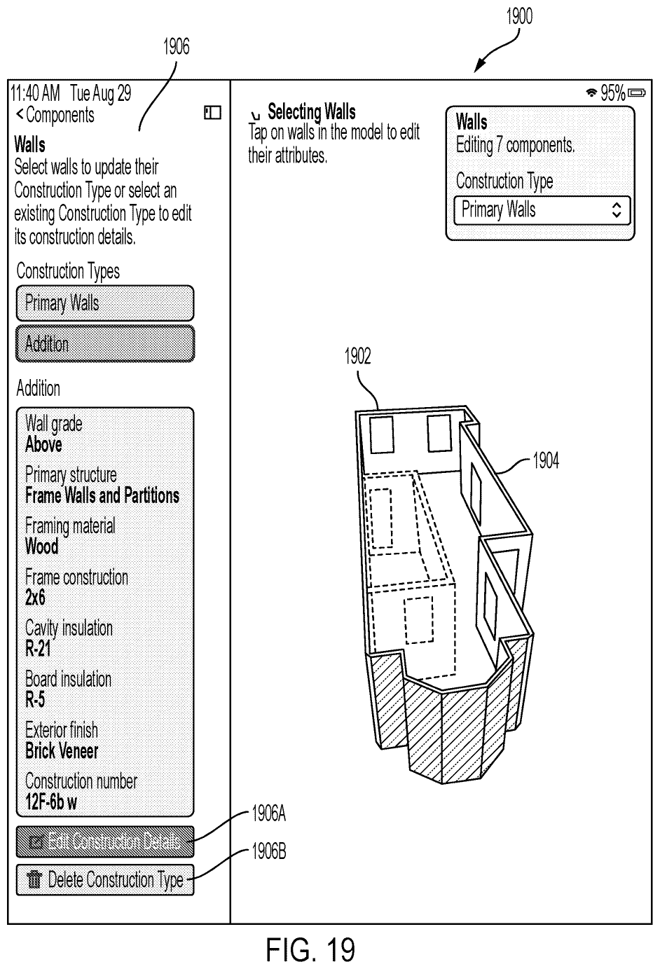

FIG. 19 illustrates an example GUI 1900 for editing attributes of a structure in a space, according to some embodiments of the technology described herein. As shown in FIG. 19, the GUI 1900 includes a display of a 3D floorplan 1902 (e.g., obtained from scanning a space using sensor(s) of a device). The GUI 1900 allows a user to select structures identified in the 3D floor plan 1902. In response to selection of a structure, the GUI 1900 displays an attribute editor 1906. In the example of FIG. 19, the user has selected the wall 1904. The attribute editor 1906 displays attributes of the selected wall 1904. The attribute editor 1906A includes an option 1906A labeled “Edit Construction Details” that, when selected, allows editing attributes (e.g., construction materials) of the selected door 1906A. The attribute editor 1906B includes an option 1906B labeled “Delete Construction Type” that, when selected, may delete the current attribute values. The user may then enter attribute values for the selected door 1904.

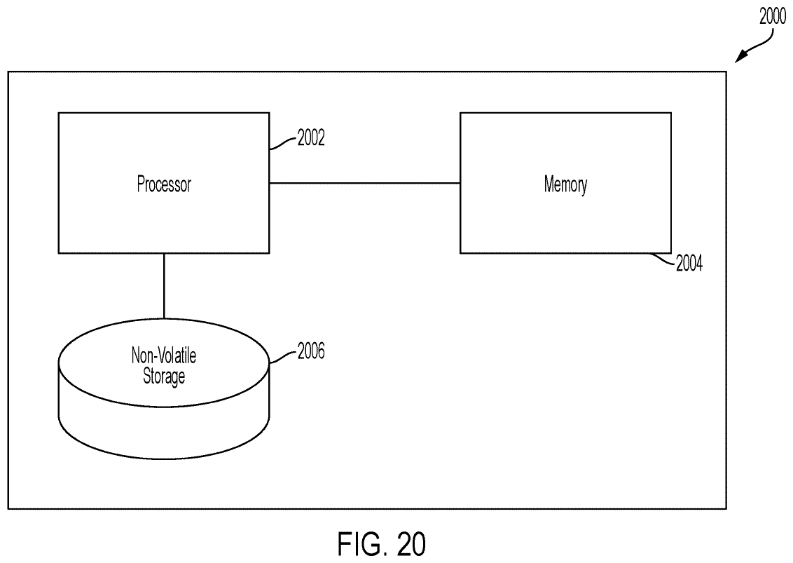

FIG. 20 is an example computer system 2000 which may be used to implement some embodiments of the technology described herein. The computing system 2000 may include one or more computer hardware processors 2002 and non-transitory computer-readable storage media (e.g., memory 2004 and one or more non-volatile storage devices 2006). The processor(s) 2002 may control writing data to and reading data from (1) the memory 2004; and (2) the non-volatile storage device(s) 2006. To perform any of the functionality described herein, the processor(s) 2002 may execute one or more processor-executable instructions stored in one or more non-transitory computer-readable storage media (e.g., the memory 2004), which may serve as non-transitory computer-readable storage media storing processor-executable instructions for execution by the processor(s) 2002.

The terms “program” or “software” are used herein in a generic sense to refer to any type of computer code or set of processor-executable instructions that can be employed to program a computer or other processor (physical or virtual) to implement various aspects of embodiments as discussed above. Additionally, according to one aspect, one or more computer programs that when executed perform methods of the disclosure provided herein need not reside on a single computer or processor, but may be distributed in a modular fashion among different computers or processors to implement various aspects of the disclosure provided herein.

Processor-executable instructions may be in many forms, such as program modules, executed by one or more computers or other devices. Generally, program modules include routines, programs, objects, components, data structures, etc. that perform tasks or implement abstract data types. Typically, the functionality of the program modules may be combined or distributed.

Various inventive concepts may be embodied as one or more processes, of which examples have been provided. The acts performed as part of each process may be ordered in any suitable way. Thus, embodiments may be constructed in which acts are performed in an order different than illustrated, which may include performing some acts simultaneously, even though shown as sequential acts in illustrative embodiments.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, for example, “at least one of A and B” (or, equivalently, “at least one of A or B.” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

Use of ordinal terms such as “first,” “second,” “third,” etc., in the claims to modify a claim element does not by itself connote any priority, precedence, or order of one claim element over another or the temporal order in which acts of a method are performed. Such terms are used merely as labels to distinguish one claim element having a certain name from another element having a same name (but for use of the ordinal term). The phraseology and terminology used herein is for the purpose of description and should not be regarded as limiting. The use of “including.” “comprising.” “having.” “containing”, “involving”, and variations thereof, is meant to encompass the items listed thereafter and additional items.

Having described several embodiments of the techniques described herein in detail, various modifications, and improvements will readily occur to those skilled in the art. Such modifications and improvements are intended to be within the spirit and scope of the disclosure. Accordingly, the foregoing description is by way of example only, and is not intended as limiting. The techniques are limited only as defined by the following claims and the equivalents thereto.

What is claimed is:

1. A system for determining a heating, ventilation, and air conditioning (HVAC) system design for a space in a building, the system comprising:
at least one imaging sensor;
at least one processor; and
a non-transitory computer-readable storage medium storing instructions that, when executed by the at least one processor, cause the at least one processor to:
obtain, using the at least one imaging sensor, spatial measurement data for the space;
determine, using the spatial measurement data, information about boundaries of the space;
perform an HVAC analysis using the information about the boundaries of the space to determine HVAC system properties suitable for the space; and
determine, using the HVAC system properties suitable for the space, an HVAC system design proposal for the space.

2. The system of claim 1, wherein the information about the boundaries of the space includes:
an indication of one or more windows in the space;
an indication of one or more walls in the space;
dimensions of the one or more windows in the space;
dimensions of the one or more walls in the space;
a surface area of the one or more windows in the space; and/or
a surface area of the one or more walls in the space.

3. The system of claim 1, wherein performing the HVAC analysis comprises:
transmitting, to at least one computer separate from the system, the information about the boundaries of the space; and
receiving, from the at least one computer, data indicating the HVAC system properties suitable for the space.

4. The system of claim 1, wherein obtaining the results of the HVAC analysis comprises:
performing, by the at least one processor, one or more HVAC system design processes using the information about the boundaries of the space to determine the HVAC system properties suitable for the space.

5. The system of claim 1, wherein the HVAC system properties determined from performing the HVAC analysis comprise an HVAC equipment size, an equipment type, and/or a duct system.

6. The system of claim 1, wherein determining, using the spatial measurement data, the information about the boundaries of the space comprises:
identifying one or more structures in the space, wherein the one or more structures include one or more walls, windows, and/or doors; and
determining dimensions of the one or more structures.

7. The system of claim 6, wherein the instructions further cause the at least one processor to:
determine, for each of the one or more structures, values of one or more attributes of the structure.

8. The system of claim 7, wherein determining, for each of the one or more structures, the values of the one or more attributes of the structure comprises:
loading a template indicating attribute values for one or more structure categories;
identifying attribute values specified by the template for a category of the structure, the attribute values comprising values for the one or more attributes of the structure; and
setting the values of the one or more attributes of the values for the one or more attributes specified by the template.

9. The system of claim 1, wherein the instructions further cause the at least one processor to:
obtain information indicating building material of the building; and
perform the HVAC analysis using the information indicating the building material of the building.

10. The system of claim 1, wherein the instructions further cause the at least one processor to:
obtain information indicating a geographic location of the building; and
perform the HVAC analysis using the geographic location of the building.

11. The system of claim 1, wherein the at least one imaging sensor comprises a light detection and ranging (LiDAR) sensor and obtaining, using the at least one imaging sensor, spatial measurement data for the space comprises:
using the LiDAR sensor to identify boundaries in the space.

12. The system of claim 1, wherein determining, using the spatial measurement data, the information about the boundaries of the space comprises:
generating a three-dimensional (3D) floorplan of the space; and
determining the information about the boundaries of the space using the 3D floor plan of the space.

13. The system of claim 12, wherein the instructions further cause the at last one processor to:
receive, through a graphical user interface (GUI), user input indicating an adjustment to the 3D floorplan of the space; and
update the 3D floorplan of the space in response to the user input.

14. The system of claim 1, wherein the HVAC system design proposal includes equipment and/or installation material and the instructions further cause the at least one processor to:
access, from a database separate from the system, pricing information for the equipment and/or the installation material.

15. The system of claim 1, wherein the instructions further cause the at least one processor to:
obtain an image of the space; and
generate a GUI indicating the boundary dimensions of the space in the image.

16. The system of claim 15, wherein the instructions further cause the at least one processor to:
receive, through the GUI, user input indicating a modification to at least one of the boundary dimensions; and
update, using the user input, the at least one boundary dimension.

17. The system of claim 1, wherein the HVAC system design proposal comprises a plurality of HVAC system designs and the instructions further cause the at least one processor to:
generate a GUI presenting the plurality of HVAC system design proposals to a user; and receiving, through the GUI, user input indicating a selected HVAC system design of the plurality of HVAC system designs.

18. The system of claim 17, wherein the instructions further cause the at least one processor to generate installation instructions and an equipment list organized by room for the selected HVAC system design.

19. A method of determining an HVAC system design for a space in a building, the method comprising:
obtaining, using at least one imaging sensor, spatial measurement data for the space;
determining, with at least one processor using the spatial measurement data, information about boundaries in the space;
performing, with the at least one processor using the boundary dimensions of the space, an HVAC analysis using the information about the boundaries of the space to determine HVAC system properties suitable for the space; and
determining, with the at least one processor using the HVAC system properties suitable for the space, an HVAC system design proposal for the space.

20. A non-transitory computer-readable storage medium storing instructions that, when executed by at least one processor, cause the at least one processor to perform a method of determining an HVAC system design for space in a building, the method comprising:
obtaining, using at least one imaging sensor, spatial measurement data for the space;
determining, using the spatial measurement data, information about boundaries in the space;
performing, using the boundary dimensions of the space, an HVAC analysis using the information about the boundaries of the space to determine HVAC system properties suitable for the space; and
determining, using the HVAC system properties suitable for the space, an HVAC system design proposal for the space.
